(19) United States
(12) Patent Application Publication
(10) Pub. No.: US 2025/0393210 A1
(43) Pub. Date: Dec. 25, 2025

(54) SEMICONDUCTOR DEVICE

(71) Applicant: Kioxia Corporation, Tokyo (JP)

(72) Inventors: Satoshi NAGASHIMA, Yokkaichi (JP); Keisuke NAKATSUKA, Kobe (JP); Yosuke MURAKAMI, Mie (JP)

(73) Assignee: Kioxia Corporation, Tokyo (JP)

(21) Appl. No.: 18/980,995

(22) Filed: Dec. 13, 2024

(30) Foreign Application Priority Data
Jun. 19, 2024 (JP) 2024-098596

(51) Int. Cl. H10B 43/27; H10B 41/10; H10B 41/27; H10B 43/10; H10B 51/10; H10B 51/20

(52) U.S. Cl. CPC H10B 43/27; H10B 41/10; H10B 41/27; H10B 43/10; H10B 51/10; H10B 51/20

(57) ABSTRACT

A semiconductor device includes: conductive layers stacked in a stacking direction; first and second conductor columns extending in the stacking direction and arranged in a first direction; an insulating column extending in the stacking direction and provided between the first and second conductor columns; a semiconductor layer formed along an outer peripheral surface of the insulating column, connected to the first and second conductor columns, and opposed to the conductive layers; and a memory film provided between the plurality of conductive layers and the semiconductor layer. In a cross-section intersecting with the stacking direction, at least a part of an outer peripheral surface of the semiconductor layer is formed approximately along a shape of a circle, an ellipse, or an oval, and at least parts of the first and second conductor columns are provided outside the shape of the circle, the ellipse, or the oval.

### CROSS-REFERENCE TO RELATED APPLICATIONS

This application is based upon and claims the benefit of Japanese Patent Application No. 2024-098596, filed on Jun. 19, 2024, the entire contents of which are incorporated herein by reference.

### BACKGROUND

### Field

Embodiments described herein relate generally to a semiconductor device.

### Description of the Related Art

In accordance with an increasing high integration of a semiconductor memory device and the like, an examination for converting the semiconductor memory device and the like into a three-dimensional form has been in progress.

### BRIEF DESCRIPTION OF THE DRAWINGS

FIG. 1 is a schematic circuit diagram illustrating a configuration of a semiconductor memory device according to a first embodiment;

FIG. 2 is a schematic plan view illustrating a configuration of the semiconductor memory device;

FIG. 3 is a schematic X-Y cross-sectional view illustrating a configuration of the semiconductor memory device;

FIG. 4 is a schematic plan view illustrating a configuration of the semiconductor memory device;

FIG. 5 is a schematic perspective view illustrating a configuration of the semiconductor memory device;

FIG. 6 is a schematic perspective view illustrating a configuration of the semiconductor memory device;

FIG. 7 is a schematic X-Y cross-sectional view illustrating a configuration of the semiconductor memory device;

FIG. 8 is a schematic X-Y cross-sectional view illustrating a configuration of the semiconductor memory device;

FIG. 9 is a schematic cross-sectional view illustrating a configuration of the semiconductor memory device;

FIG. 10 is a schematic cross-sectional view for describing a manufacturing method of the semiconductor memory device;

FIG. 11 is a schematic cross-sectional view for describing the manufacturing method;

FIG. 12 is a schematic cross-sectional view for describing the manufacturing method; FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view illustrating a configuration of a part of a semiconductor memory device according to a second embodiment;

FIG. 31 is a schematic cross-sectional view illustrating a configuration of a part of the semiconductor memory device according to the second embodiment;

FIG. 32 is a schematic cross-sectional view illustrating a configuration of a part of the semiconductor memory device according to the second embodiment;

FIG. 33 is a schematic cross-sectional view for describing a manufacturing method of the semiconductor memory device;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view illustrating a configuration of a part of a semiconductor memory device according to a third embodiment;

FIG. 45 is a schematic cross-sectional view illustrating a configuration of a part of the semiconductor memory device according to the third embodiment;

FIG. 46 is a schematic cross-sectional view illustrating a configuration of a part of the semiconductor memory device according to the third embodiment;

FIG. 47 is a schematic cross-sectional view illustrating a configuration of a part of a semiconductor memory device according to a fourth embodiment;

FIG. 48 is a schematic cross-sectional view illustrating a configuration of a part of the semiconductor memory device according to the fourth embodiment;

FIG. 49 is a schematic cross-sectional view illustrating a configuration of a part of the semiconductor memory device according to the fourth embodiment;

FIG. 50 is a schematic cross-sectional view for describing a manufacturing method of the semiconductor memory device;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view illustrating a configuration of a part of a semiconductor memory device according to a fifth embodiment;

FIG. 65 is a schematic cross-sectional view illustrating a configuration of a part of the semiconductor memory device according to the fifth embodiment;

FIG. 66 is a schematic cross-sectional view illustrating a configuration of a part of the semiconductor memory device according to the fifth embodiment;

FIG. 67 is a schematic cross-sectional view for describing a manufacturing method of the semiconductor memory device;

FIG. 68 is a schematic cross-sectional view for describing the manufacturing method;

FIG. 69 is a schematic cross-sectional view for describing the manufacturing method;

FIG. 70 is a schematic cross-sectional view for describing the manufacturing method;

FIG. 71 is a schematic cross-sectional view for describing the manufacturing method;

FIG. 72 is a schematic cross-sectional view for describing the manufacturing method;

FIG. 73 is a schematic cross-sectional view for describing the manufacturing method;

FIG. 74 is a schematic cross-sectional view for describing the manufacturing method;

FIG. 75 is a schematic cross-sectional view for describing the manufacturing method;

FIG. 76 is a schematic cross-sectional view for describing the manufacturing method;

FIG. 77 is a schematic cross-sectional view for describing the manufacturing method;

FIG. 78 is a schematic cross-sectional view for describing the manufacturing method;

FIG. 79 is a schematic cross-sectional view for describing the manufacturing method;

FIG. 80 is a schematic cross-sectional view for describing the manufacturing method;

FIG. 81 is a schematic cross-sectional view for describing the manufacturing method;

FIG. 82 is a schematic cross-sectional view illustrating a configuration of a part of a semiconductor memory device according to a sixth embodiment;

FIG. 83 is a schematic cross-sectional view illustrating a configuration of a part of the semiconductor memory device according to the sixth embodiment;

FIG. 84 is a schematic cross-sectional view illustrating a configuration of a part of the semiconductor memory device according to the sixth embodiment;

FIG. 85 is a schematic cross-sectional view for describing a manufacturing method of the semiconductor memory device;

FIG. 86 is a schematic cross-sectional view for describing the manufacturing method;

FIG. 87 is a schematic cross-sectional view for describing the manufacturing method;

FIG. 88 is a schematic cross-sectional view for describing the manufacturing method;

FIG. 89 is a schematic cross-sectional view for describing the manufacturing method;

FIG. 90 is a schematic cross-sectional view for describing the manufacturing method;

FIG. 91 is a schematic cross-sectional view for describing the manufacturing method;

FIG. 92 is a schematic cross-sectional view for describing the manufacturing method;

FIG. 93 is a schematic cross-sectional view for describing the manufacturing method;

FIG. 94 is a schematic cross-sectional view for describing the manufacturing method;

FIG. 95 is a schematic cross-sectional view for describing the manufacturing method;

FIG. 96 is a schematic cross-sectional view for describing the manufacturing method;

FIG. 97 is a schematic cross-sectional view for describing a manufacturing method of a semiconductor memory device according to a seventh embodiment;

FIG. 98 is a schematic cross-sectional view for describing the manufacturing method;

FIG. 99 is a schematic cross-sectional view for describing the manufacturing method; and

FIG. 100 is a schematic cross-sectional view for describing the semiconductor memory device according to the seventh embodiment.

### DETAILED DESCRIPTION

A semiconductor device according to one embodiment comprises: a plurality of conductive layers stacked in a stacking direction; a first conductor column and a second conductor column extending in the stacking direction and arranged in a first direction intersecting with the stacking direction; an insulating column extending in the stacking direction and provided between the first conductor column and the second conductor column; a semiconductor layer formed along an outer peripheral surface of the insulating column, connected to the first conductor column and the second conductor column, and opposed to the plurality of conductive layers; and a memory film provided between the plurality of conductive layers and the semiconductor layer. In a cross-section intersecting with the stacking direction, at least a part of an outer peripheral surface of the semiconductor layer is formed approximately along a shape of a circle, an ellipse, or an oval, and at least a part of the first conductor column and at least a part of the second conductor column are provided outside the shape of the circle, the ellipse, or the oval.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, a direction parallel to a surface of the substrate is referred to as an X-direction, a direction parallel to the surface of the substrate and perpendicular to the X-direction is referred to as a Y-direction, and a direction perpendicular to the surface of the substrate is referred to as a Z-direction.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, a direction intersecting with a surface of the substrate is referred to as a stacking direction in some cases. A direction along a predetermined plane intersecting with the stacking direction may be referred to as a first direction, and a direction along the plane and intersecting with the first direction may be referred to as a second direction. The stacking direction may correspond to the Z-direction and need not correspond to the Z-direction. The first direction and the second direction may and need not each correspond to any of the X-direction or the Y-direction as well as X′-direction or the Y′-direction described later.

### First Embodiment

### [Circuit Configuration]

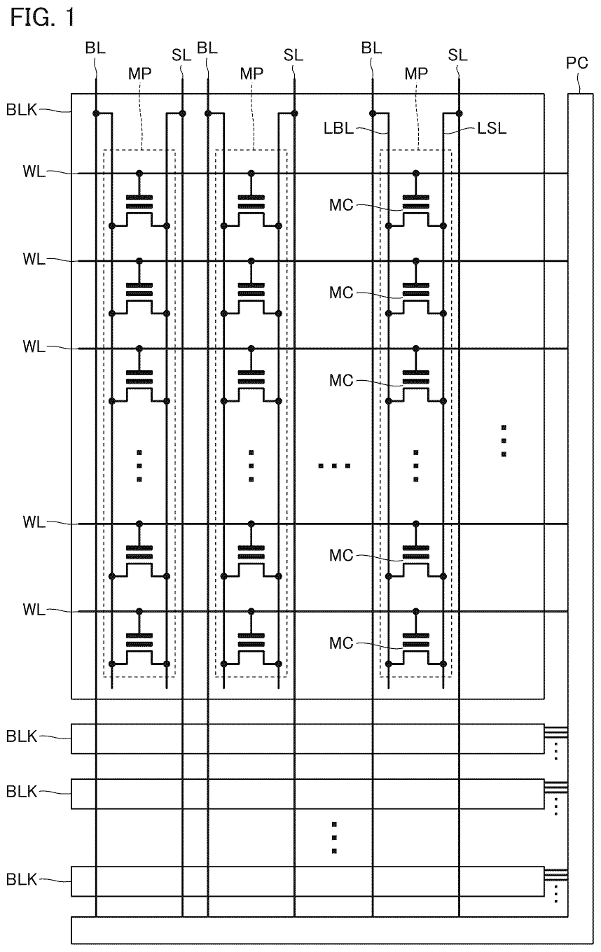

FIG. 1 is a schematic circuit diagram illustrating a configuration of a semiconductor memory device according to a first embodiment. The semiconductor memory device according to the embodiment includes a plurality of memory blocks BLK, a plurality of bit lines BL connected to the plurality of memory blocks BLK in common, a plurality of source lines SL connected to the plurality of memory blocks BLK in common, and a peripheral circuit PC connected to the plurality of memory blocks BLK, the plurality of bit lines BL, and the plurality of source lines SL.

Each of the plurality of memory blocks BLK includes a plurality of word lines WL and a plurality of memory pillars MP. Each of the plurality of memory pillars MP includes a local bit line LBL, a local source line LSL, and a plurality of memory cells MC connected in parallel between the local bit line LBL and the local source line LSL. Each of the plurality of word lines WL is connected to all of the memory pillars MP in the memory block BLK in common.

Each of the plurality of memory cells MC is a field-effect type transistor, and includes a drain electrode connected to the local bit line LBL, a source electrode connected to the local source line LSL, and a control gate electrode connected to the word line WL. The memory cell MC also includes an electric charge accumulating film provided between a channel region and the control gate electrode. The memory cell MC has a threshold voltage that changes according to an electric charge amount in the electric charge accumulating film. The memory cell MC stores one bit or a plurality of bits of user data.

Each memory block BLK includes a plurality of local bit lines LBL corresponding to the plurality of bit lines BL, and a plurality of local source lines LSL corresponding to the plurality of source lines SL. The respective plurality of bit lines BL are connected in common to the respective corresponding local bit lines LBL in all the memory blocks BLK. The respective plurality of source lines SL are connected in common to the respective corresponding local source line LSL in all the memory blocks BLK.

The peripheral circuit PC, for example, includes a voltage generation circuit, a decode circuit, a sense amplifier, and a sequencer. The voltage generation circuit generates voltages used in a read operation, a write operation, and an erase operation, and the like. The decode circuit applies the generated voltages to each wire according to address data. The sense amplifier senses a voltage or a current of the bit line BL to read the user data stored in the memory cell MC and switches the voltage of the bit line BL according to the user data to be stored in the memory cell MC. The sequencer controls these circuits according to input command data and executes the read operation, the write operation, the erase operation, and the like.

The peripheral circuit PC, for example, selects one memory block BLK for the read operation, and further selects one word line WL. The peripheral circuit PC applies the read voltage to the selected word line WL and applies a non-select voltage to unselected word lines WL. The read voltage is a voltage having a magnitude for causing the memory cell MC to enter ON state or OFF state, depending on the data stored in the memory cell MC. The non-select voltage is a voltage having a magnitude for causing the memory cell MC to enter the OFF state, regardless of the data stored in the memory cell MC.

In addition, the peripheral circuit PC, for example, applies a voltage difference between the bit line BL and the source line SL for the read operation. As a result, a part of the plurality of memory cells MC connected to the selected word line WL enters the ON state, and the current flows through the corresponding bit lines BL. On the other hand, the other part of the plurality of memory cells MC connected to the selected word line WL does not enter the ON state, and no current flows through the corresponding bit lines BL.

In addition, the peripheral circuit PC, for example, applies predetermined voltages to the plurality of word lines WL, the plurality of bit lines BL, and the plurality of source lines SL in the one selected memory block BLK during the erase operation, and causes them to function as a NOR flash memory that erases all the data stored in the memory cells MC in the selected memory block BLK at once.

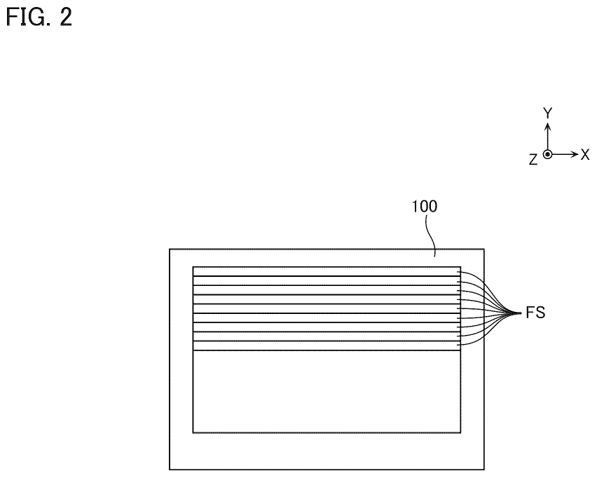

FIG. 2 is a schematic plan view of a configuration of the semiconductor memory device according to the embodiment. The semiconductor memory device according to the embodiment includes a semiconductor substrate 100 and a plurality of finger structures FS provided on the semiconductor substrate 100. In the illustrated example, these plurality of finger structures FS are arranged in a Y-direction and each extend in an X-direction. In this embodiment, each of these plurality of finger structures FS functions as the memory block BLK (FIG. 1).

### [Structure]

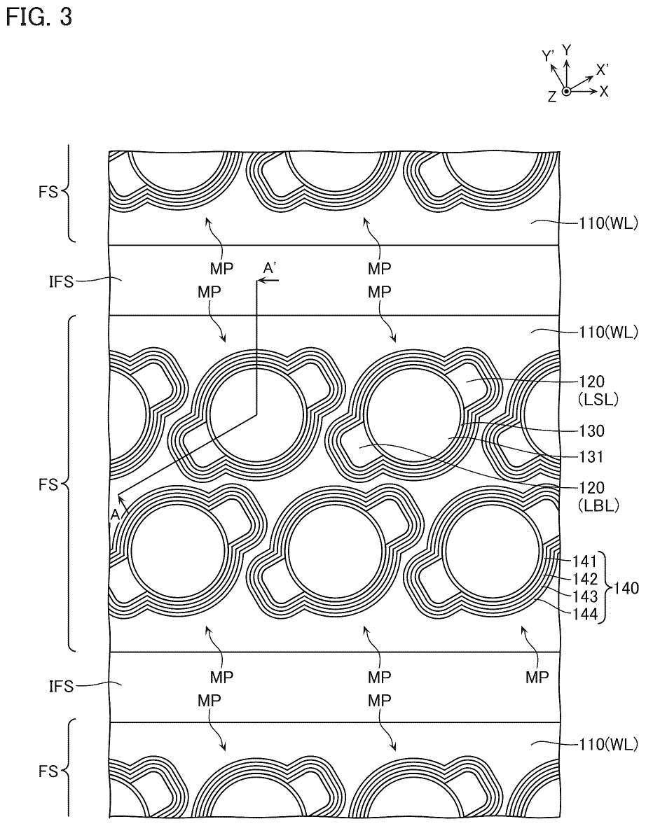

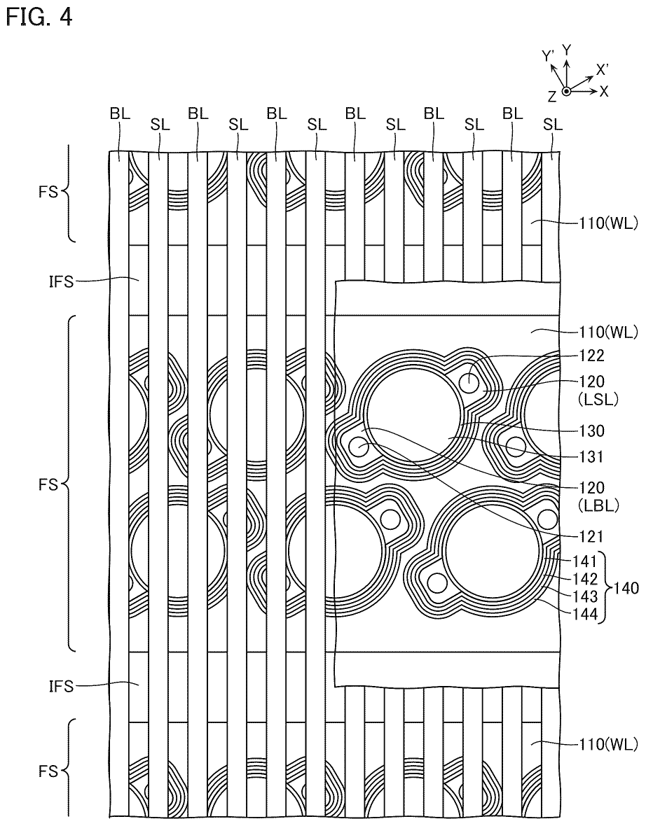

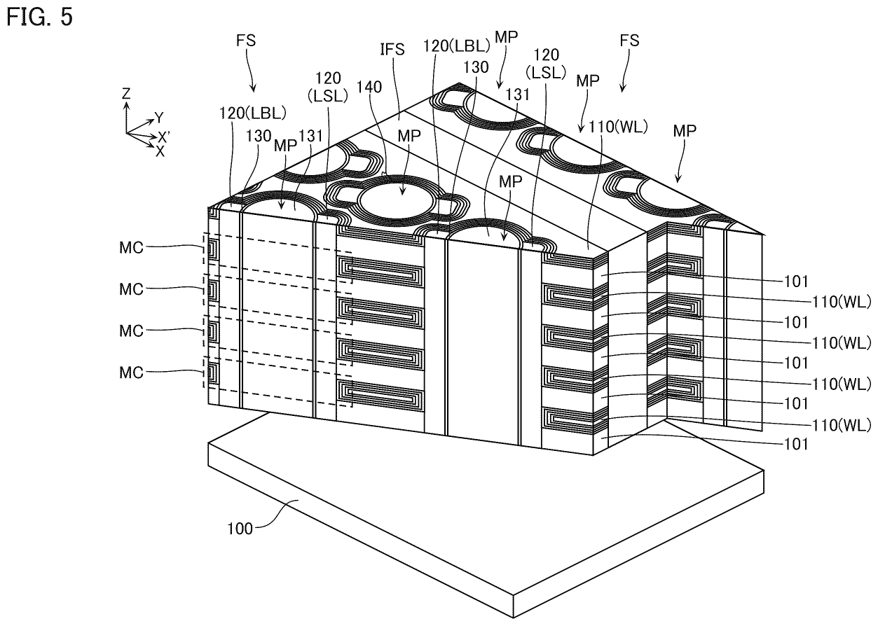

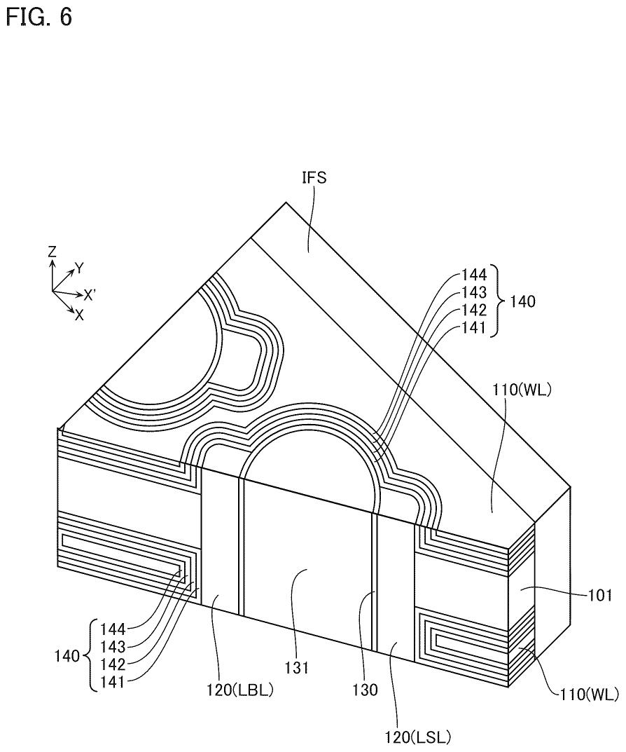

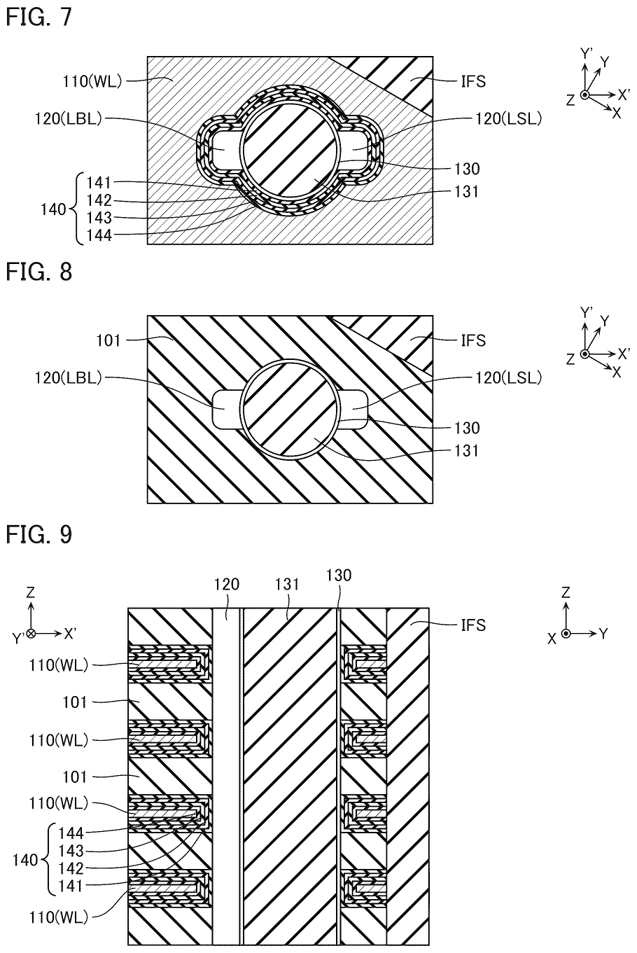

FIG. 3 is a schematic X-Y cross-sectional view illustrating a configuration of the semiconductor memory device according to the embodiment. FIG. 4 is a schematic plan view illustrating a configuration of the semiconductor memory device according to the embodiment. FIG. 4 illustrates a plan view of a region corresponding to FIG. 3. FIG. 4 illustrates the bit lines BL, source lines SL, and the like. FIGS. 5 and 6 are schematic perspective views illustrating configurations of the semiconductor memory device according to the embodiment. FIGS. 7 and 8 are schematic X-Y cross-sectional views illustrating configurations of the semiconductor memory device according to the embodiment. FIGS. 7 and 8 are schematic views for a purpose of description, and illustrate only one memory pillar MP. FIG. 7 illustrates a cross-section at a height position corresponding to a conductive layer 110 described later. FIG. 8 illustrates a cross-section at a height position corresponding to an insulating layer 101 described later. FIG. 9 is a schematic cross-sectional view illustrating a configuration of the semiconductor memory device according to the embodiment. FIG. 9 illustrates a cross-section of a structure illustrated in FIG. 3 cut along the A-A′ line and viewed along a direction of the arrow.

In addition to the X-direction, the Y-direction, and a Z-direction, FIGS. 3 to 9 illustrate an X′-direction and a Y′-direction. The X′-direction and the Y′-direction are directions within an XY plane. The X′-direction is a direction in which the X-direction has been rotated approximately 30° about the Z-direction. The Y′-direction is a direction in which the Y-direction has been rotated approximately 30° about the Z-direction. The X′-direction and the Y′-direction are perpendicular to each other.

As illustrated in FIG. 5, the finger structure FS includes the plurality of conductive layers 110 and the plurality of insulating layers 101 arranged alternately in the Z-direction, and the plurality of memory pillars MP extending in the Z-direction penetrating through these plurality of conductive layers 110 and insulating layers 101. In addition, an inter-finger insulating member IFS is provided between two finger structures FS adjacent to each other in the Y-direction.

The conductive layer 110 has an approximately plate-like shape extending in the X-direction. The conductive layer 110 may include a stacked film and the like of a barrier conductive film of such as titanium nitride (TiN) and a metal film of such as tungsten (W). The conductive layer 110 may also include, for example, polycrystalline silicon and the like, which contains impurities such as phosphorus (P) or boron (B). The conductive layer 110 functions as the word line WL and the control gate electrodes of the memory cells MC, as described with reference to FIG. 1. The insulating layer 101 includes silicon oxide (SiO₂) and the like.

As illustrated in FIG. 3, for example, the memory pillars MP are arranged in two rows in the X-direction in each finger structure FS. The memory pillar MP, as illustrated in FIG. 5, includes, for example, a pair of conductor columns 120 and a semiconductor layer 130 connected to the pair of conductor columns 120. In addition, the memory pillar MP, as illustrated in FIG. 6, includes, for example, a gate insulating film 140 (memory film) provided between the conductive layers 110 and the semiconductor layer 130.

For example, as illustrated in FIG. 3, a pair of conductor columns 120 are spaced in the X′-direction at each memory pillar MP. In addition, the semiconductor layer 130 is provided between the pair of conductor columns 120 and is in contact with the pair of conductor columns 120. In the X-Y cross-section illustrated in FIG. 3, an inner peripheral surface and an outer peripheral surface of the semiconductor layer 130 are formed approximately along a circle. The pair of conductor columns 120 are provided outside these circles. The pair of conductor columns 120 are formed in an approximately rectangular shape with two sides extending in the X′-direction. A length in the Y′-direction of the conductor column 120 is smaller than a diameter of the circle along the outer peripheral surface of the semiconductor layer 130. A surface on the other conductor column 120 side of one conductor column 120 in the X′-direction is in contact with the semiconductor layer 130. Similarly, a surface on the one conductor column 120 side of the other conductor column 120 in the X′-direction is in contact with the semiconductor layer 130.

In the X-Y cross-section illustrated in FIG. 3, the gate insulating film 140 is formed along the outer peripheral surfaces of the pair of conductor columns 120 and the semiconductor layer 130. In other words, portions other than the contact surfaces with the conductor columns 120 of the outer peripheral surface of the semiconductor layer 130 are in contact with the gate insulating film 140. In addition, portions other than the contact surfaces with the semiconductor layer 130 of outer peripheral surfaces of the conductor columns 120 (the surface on a side opposite to the other conductor column 120 in the X′-direction, and both surfaces in the Y′-direction) are in contact with the gate insulating film 140. The conductive layer 110 surrounds the pair of conductor columns 120 and the semiconductor layer 130 via the gate insulating film 140.

Each of the pair of the conductor columns 120 is continuous in the Z-direction within a range in the Z-direction in which the plurality of conductive layers 110 are provided. Therefore, as illustrated in FIGS. 7 to 9, each of the pair of the conductor columns 120 is provided at height positions corresponding to the conductive layers 110 and also at height positions corresponding to the insulating layers 101.

One of the pair of conductor columns 120 functions as the local bit line LBL, and the other functions as the local source line LSL as described with reference to FIG. 1. The conductor column 120 has at least a resistivity that is lower than a resistivity of the semiconductor layer 130. The conductor column 120 may include, for example, a semiconductor column, such as polycrystalline silicon, which contains impurities such as phosphorus (P) or boron (B), or it may include a metal column, or it may include both of these. In addition, when the conductor column 120 includes a semiconductor column such as polycrystalline silicon that contains impurities such as phosphorus (P) or boron (B), the semiconductor layer 130 does not contain any impurity, or a concentration of impurities contained in the semiconductor layer 130 is lower than a concentration of impurities in the conductor column 120.

The semiconductor layer 130 is continuous in the Z-direction within the range in the Z-direction in which the plurality of conductive layers 110 are provided, and is opposed to the plurality of conductive layers 110 arranged in the Z-direction. Therefore, as illustrated in FIGS. 7 to 9, the semiconductor layer 130 is provided at the height positions corresponding to the conductive layers 110 and also at the height positions corresponding to the insulating layers 101.

The semiconductor layer 130 contains, for example, polycrystalline silicon (Si). The semiconductor layer 130 has an approximately cylindrical shape, and an insulating column 131, such as silicon oxide (SiO₂), is provided in the central portion. The semiconductor layer 130 functions as the channel regions of the plurality of memory cells MC arranged in the Z-direction.

The gate insulating film 140 is divided in the Z-direction in correspondence with the plurality of conductive layers 110 arranged in the Z-direction. In other words, as illustrated in FIGS. 7 and 9, the gate insulating films 140 are provided at the height positions corresponding to the conductive layers 110. However, as illustrated in FIGS. 8 and 9, the gate insulating film 140 is not provided at any of the height positions corresponding to the insulating layers 101.

As illustrated in FIG. 6, for example, the gate insulating film 140 includes a tunnel insulating film 141, an electric charge accumulating film 142, and block insulating films 143 and 144 stacked between the semiconductor layer 130 and the conductive layers 110. The tunnel insulating film 141 and the block insulating film 143 contain, for example, silicon oxide (SiO₂). The electric charge accumulating film 142 includes, for example, a film capable of accumulating electric charge, such as silicon nitride (SiN), and is capable of charging an amount of electric charge corresponding to the data stored in the memory cell MC. The block insulating film 144 includes a high-dielectric metal oxide film, such as alumina (Al₂O₃), for example. In the illustrated example, top surface, bottom surface, and surfaces opposed to the semiconductor layers 130 and the conductor columns 120 of the conductive layer 110 are sequentially provided with the block insulating films 144 and 143, the electric charge accumulating film 142, and the tunnel insulating film 141.

As illustrated in FIG. 4, above the plurality of finger structures FS arranged in the Y-direction, the plurality of bit lines BL and the plurality of source lines SL are provided extending in the Y-direction and arranged alternately in the X-direction. Each of the plurality of memory pillars MP is disposed such that one conductor column 120 overlaps with one of the bit lines BL when viewed from the Z-direction and the other conductor column 120 overlaps with one of the source lines SL when viewed from the Z-direction. The bit lines BL are each connected to one of the conductor columns 120 via a contact electrode 121. The source line SL is connected to the other of the conductor columns 120 via a contact electrode 122.

### [Manufacturing Method]

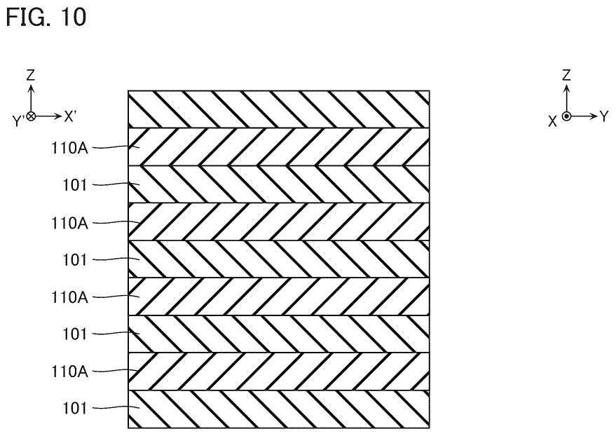

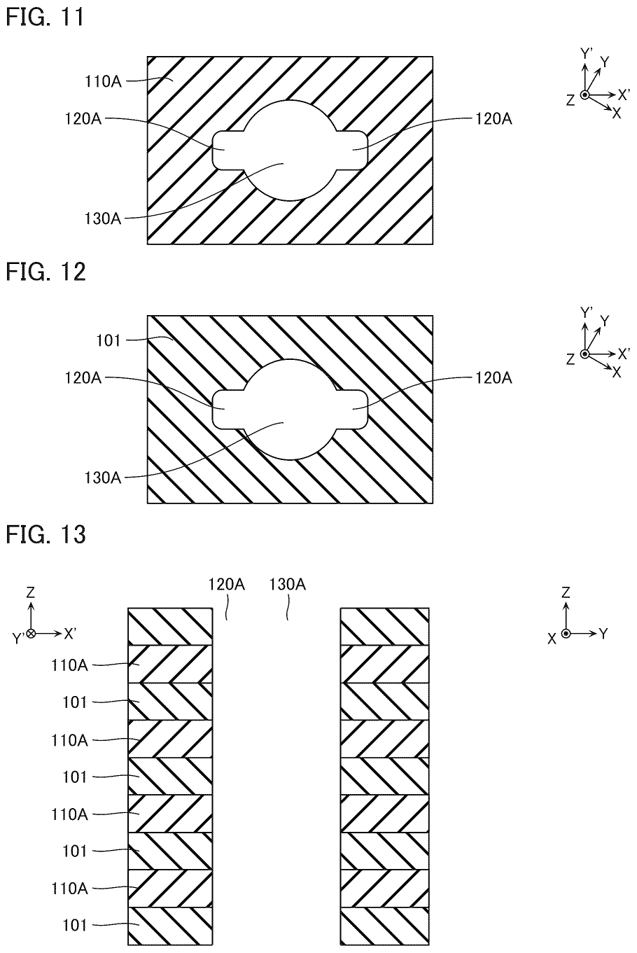

Next, referring to FIGS. 10 to 29, a manufacturing method of the semiconductor memory device according to the first embodiment is described. FIG. 10 to FIG. 29 are schematic cross-sectional views for describing the manufacturing method. FIGS. 11, 14, 17, 20, 23, 26, and 28 illustrate cross-sections corresponding to FIG. 7. FIGS. 12, 15, 18, 21, and 24 illustrate cross-sections corresponding to FIG. 8. FIGS. 10, 13, 16, 19, 22, 25, 27, and 29 illustrate cross-sections corresponding to FIG. 9.

In manufacturing the semiconductor memory device according to the embodiment, for example, as illustrated in FIG. 10, a plurality of insulating layers 101 and a plurality of sacrifice layers 110A are formed alternately. This process is performed by a method, such as chemical vapor deposition (CVD), for example.

Next, for example, as illustrated in FIGS. 11 to 13, openings 120A are formed in positions corresponding to the conductor columns 120, and an opening 130A is formed in a position corresponding to the semiconductor layer 130. In the examples of FIGS. 11 and 12, the opening 130A is formed approximately along a circle. A pair of the openings 120A are provided outside this circle and is continuous with the opening 130A. The pair of openings 120A are formed in an approximately rectangular shape, and lengths in the Y′-direction of the openings 120A are smaller than a diameter of the opening 130A. Openings 120A and 130A extend in the Z-direction and penetrate through the plurality of insulating layers 101 and the plurality of sacrifice layers 110A. This process is performed by a method, such as Reactive Ion Etching (RIE), for example.

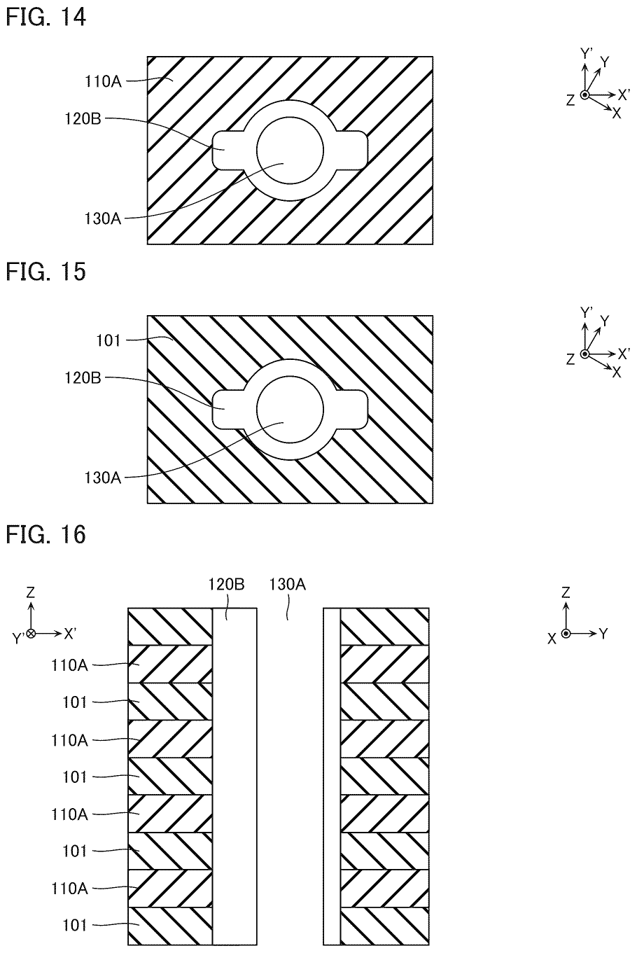

Next, as illustrated in FIGS. 14 to 16, for example, a conductor layer 120B is formed inside the openings 120A and 130A. The conductor layer 120B is formed with a thickness that is sufficient to fill the openings 120A but not to fill the opening 130A. This process is performed by a method, such as CVD, for example.

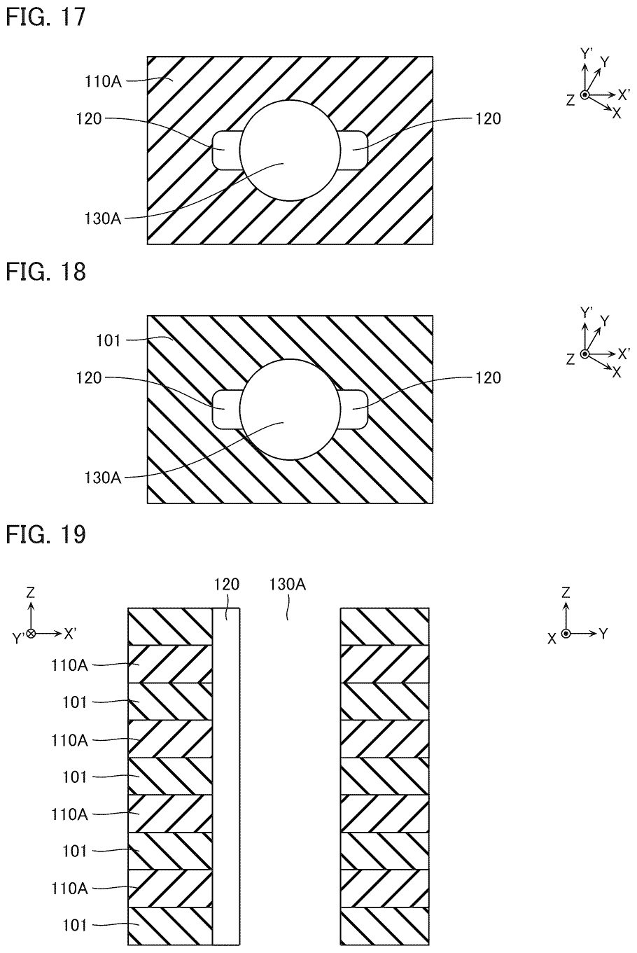

Next, for example, as illustrated in FIGS. 17 to 19, the conductor columns 120 are formed. For example, portions formed in the openings 120A of the conductor layer 120B are left, and a portion formed in the opening 130A of the conductor layer 120B is removed. This process is performed by a method, such as wet etching, for example.

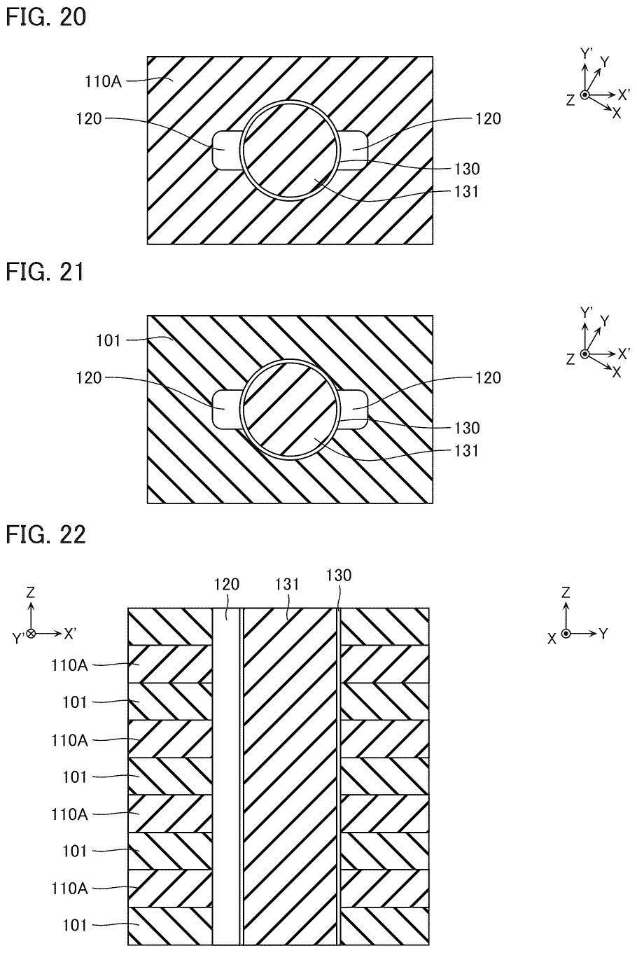

Next, as illustrated in FIGS. 20 to 22, for example, the semiconductor layer 130 and the insulating column 131 are formed inside the opening 130A. This process is performed by a method, such as CVD, for example.

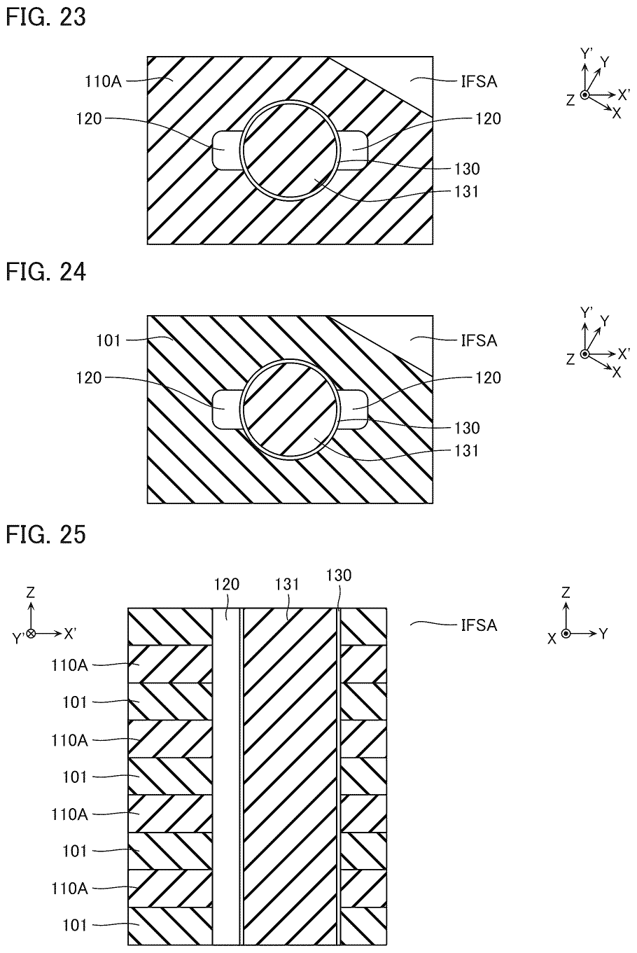

Next, as illustrated in FIGS. 23 to 25, for example, a trench IFSA is formed at a position corresponding to the inter-finger insulating member IFS. The trench IFSA extends in the Z-direction and the X-direction, and divides the plurality of insulating layers 101 and the plurality of sacrifice layers 110A in the Y-direction. This process is performed by a method, such as RIE, for example.

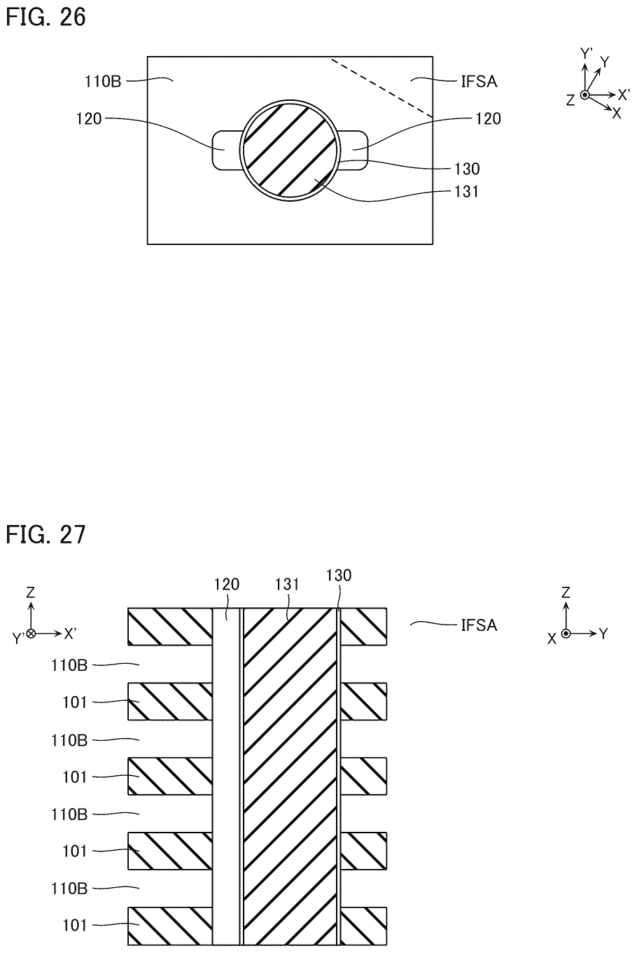

Next, for example, the sacrifice layers 110A are removed through the trench IFSA illustrated in FIGS. 26 and 27 to form a plurality of cavities 110B. This forms a hollow structure that includes the plurality of insulating layers 101 arranged in the Z-direction and includes the conductor columns 120, the semiconductor layer 130, and the insulating column 131 that support the plurality of insulating layers 101. This process is performed by a method, such as wet etching, for example.

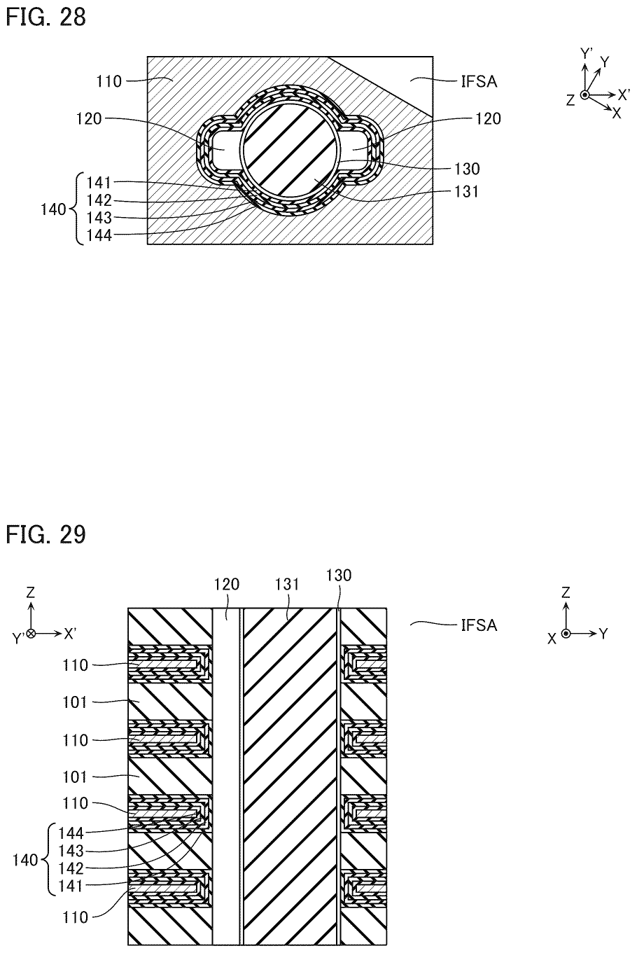

Next, as illustrated in FIGS. 28 and 29, for example, the gate insulating films 140 and the conductive layers 110 are formed in the cavities 110B. This process is performed by a method, such as CVD, for example.

Subsequently, by forming the inter-finger insulating members IFS, the bit lines BL, the source lines SL, and the like, the semiconductor memory device according to the first embodiment is formed.

### [Effect]

The semiconductor memory devices according to the first embodiment and respective embodiments described later allow increasing the number of the conductive layers 110 stacked in the Z-direction by increasing the number of the sacrifice layers 110A and the insulating layers 101 in the process described with reference to FIG. 10. With such a configuration, it is possible to manufacture a NOR flash memory with a high level of integration relatively easily.

Here, as described with reference to FIG. 1, the NOR flash memory includes the local bit lines LBL, the local source lines LSL, the plurality of memory cells MC connected in parallel between these lines, and the plurality of word lines WL connected to the gate electrodes of these plurality of memory cells MC.

In order to achieve such a structure, for example, it is possible to form holes respectively corresponding to the local bit line LBL, the local source line LSL, the channel regions of the memory cells MC, and the like. However, with such a method, it is necessary to precisely position these plurality of holes, which increases the manufacturing difficulty.

Therefore, for example, as described with reference to FIGS. 11 to 13, the circular opening 130A and the openings 120A having the approximately rectangular shape are formed together. In the processes described with reference to FIGS. 14 to 19, the conductor columns 120 are formed inside the openings 120A, and in the processes described with reference to FIGS. 20 to 22, the semiconductor layer 130 is formed inside the opening 130A. With such a method, there is no need to adjust the positional relation between the local bit line LBL, the local source line LSL, and the channel regions of the memory cells MC, and it is easy to achieve the semiconductor memory device.

### Second Embodiment

### [Structure]

Next, referring to FIGS. 30 to 32, a semiconductor memory device according to a second embodiment is described. FIGS. 30 to 32 are schematic cross-sectional views illustrating configurations of parts of the semiconductor memory device according to the second embodiment, and illustrate the respective configurations in positions corresponding to those in FIGS. 7 to 9. In the following description, the same reference numerals are used for the same parts as those of the semiconductor memory device according to the first embodiment, and their descriptions may be omitted.

The semiconductor memory device according to the second embodiment is basically configured similarly to the semiconductor memory device according to the first embodiment. However, the semiconductor memory device according to the second embodiment includes a semiconductor layer 230 instead of the semiconductor layer 130.

The semiconductor layer 230 is divided in the Z-direction in correspondence with the plurality of conductive layers 110 arranged in the Z-direction. In other words, as illustrated in FIGS. 30 and 32, the semiconductor layers 230 are provided at the height positions corresponding to the conductive layers 110.

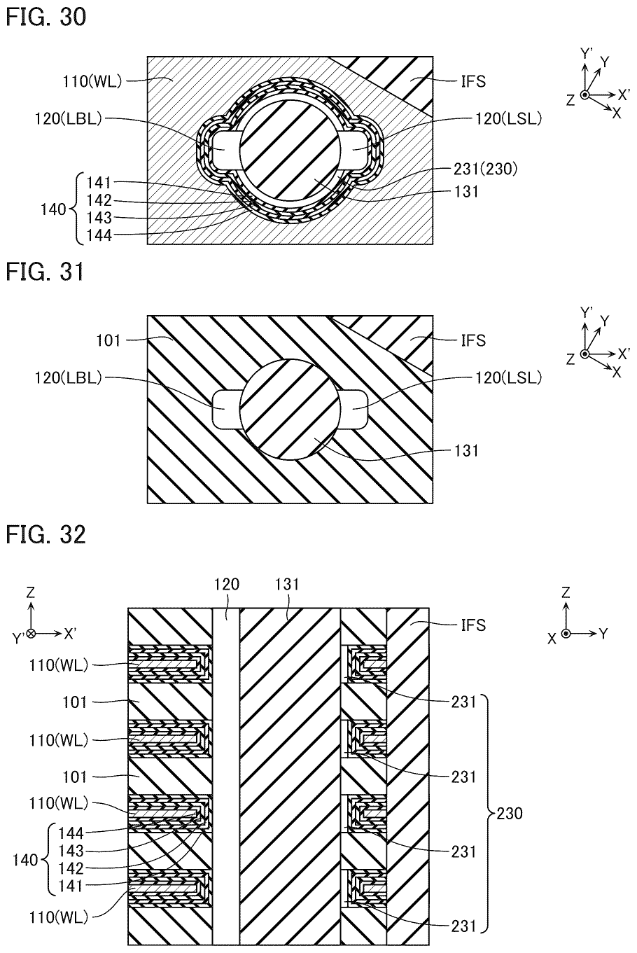

However, as illustrated in FIGS. 31 and 32, the semiconductor layer 230 is not provided at any of the height positions corresponding to the insulating layers 101. Parts of the semiconductor layer 230 divided in the Z-direction are referred to as semiconductor portions 231.

Each of the semiconductor portions 231 is opposed to one corresponding conductive layer 110. The semiconductor portion 231 contains, for example, polycrystalline silicon (Si) and the like. Each of the plurality of semiconductor portions 231 arranged in the Z-direction is divided in the Y′-direction via the pair of conductor columns 120, and the insulating column 131 is provided between the pair of conductor columns 120. Each of the semiconductor portions 231 functions as the channel region of the memory cell MC.

For example, as illustrated in FIG. 30, the insulating column 131 is provided between the pair of conductor columns 120, and is in contact with the pair of conductor columns 120. In the X-Y cross-section illustrated in FIG. 30, an outer peripheral surface of the insulating column 131 is formed approximately along a circle. The pair of conductor columns 120 are provided outside this circle. The length in the Y′-direction of the conductor column 120 is smaller than the diameter of the circle along the outer peripheral surface of the insulating column 131. A surface on the other conductor column 120 side in the X′-direction of one conductor column 120 is in contact with the insulating column 131. Similarly, a surface on the one conductor column 120 side in the X′-direction of the other conductor column 120 is in contact with the insulating column 131.

The semiconductor portion 231 is formed along the outer peripheral surface of the insulating column 131, and as described above, it is divided in the Y′-direction via the pair of conductor columns 120. An outer peripheral surface of the semiconductor portion 231 is formed approximately along a circle. The pair of conductor columns 120 are mainly provided on the outside of this circle, but each also has a portion provided on the inside of this circle. Among both the surfaces in the Y′-direction of the pair of conductor columns 120, a contact portion with the semiconductor portion 231 is provided in proximity to the contact surface with the insulating column 131.

In the X-Y cross-section illustrated in FIG. 30, the gate insulating film 140 is formed along the outer peripheral surfaces of the pair of conductor columns 120 and the semiconductor portion 231. In other words, the outer peripheral surface of the semiconductor portion 231 is in contact with the gate insulating film 140. In addition, a portion other than the contact surface with the insulating column 131 and a contact surface with the semiconductor portion 231 of the outer peripheral surface of the conductor column 120 (the surface on a side opposite to other conductor column 120 in the X′-direction, and both surfaces in the Y′-direction other than the contact portion with the semiconductor portion 231) is in contact with the gate insulating film 140. The conductive layer 110 surrounds the pair of conductor columns 120 and the semiconductor portion 231 via the gate insulating film 140.

### [Manufacturing Method]

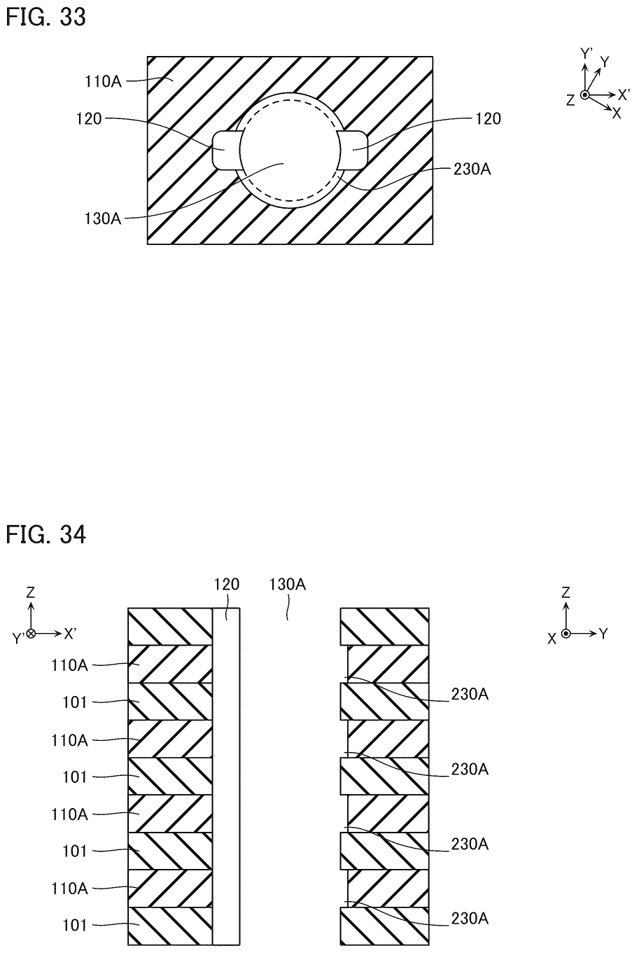

Next, referring to FIGS. 33 to 43, a manufacturing method of the semiconductor memory device according to the second embodiment is described. FIGS. 33 to 43 are schematic cross-sectional views for describing the manufacturing method. FIGS. 33, 35, 38, and 41 illustrate cross-sections corresponding to FIG. 30. FIGS. 36, 39, and 42 illustrate cross-sections corresponding to FIG. 31. FIGS. 34, 37, 40, and 43 illustrate cross-sections corresponding to FIG. 32.

In manufacturing the semiconductor memory device according to the second embodiment, for example, the processes up to the processes described with reference to FIGS. 17 to 19 in the manufacturing method of the semiconductor memory device according to the first embodiment are performed.

Next, as illustrated in FIGS. 33 and 34, portions of the sacrifice layers 110A are removed inside the opening 130A to form recessed portions 230A. In this process, the conductor columns 120 are not removed. Therefore, each of the plurality of recessed portions 230A formed at each height position has two parts separated in the Y′-direction by the conductor columns 120. This process is performed, for example, by wet etching.

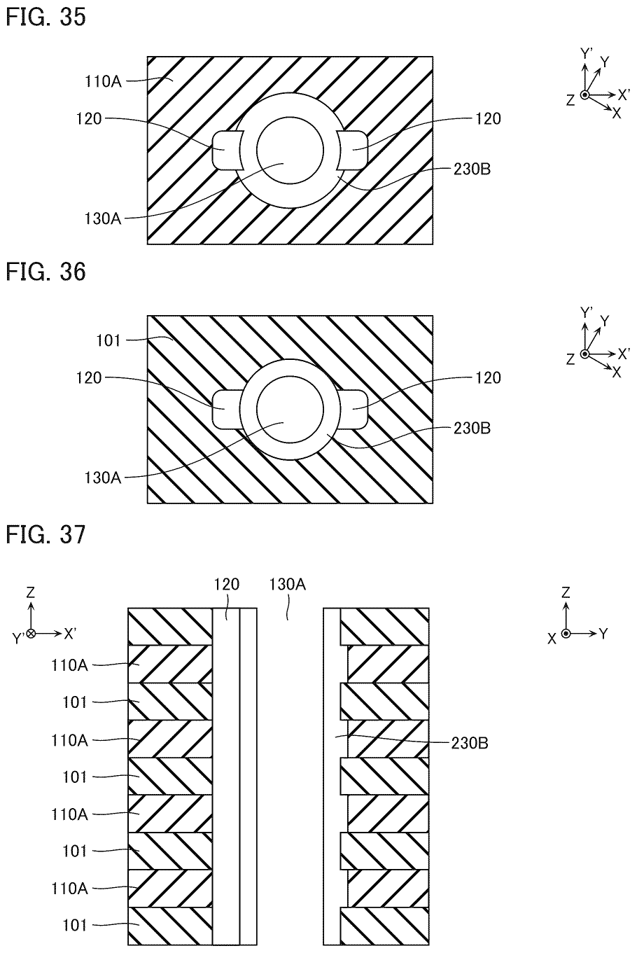

Next, as illustrated in FIGS. 35 to 37, a semiconductor layer 230B is formed inside the opening 130A and the recessed portions 230A. The semiconductor layer 230B is formed with a thickness that is sufficient to fill the recessed portions 230A, but not to fill the opening 130A. This process is performed by a method, such as CVD, for example.

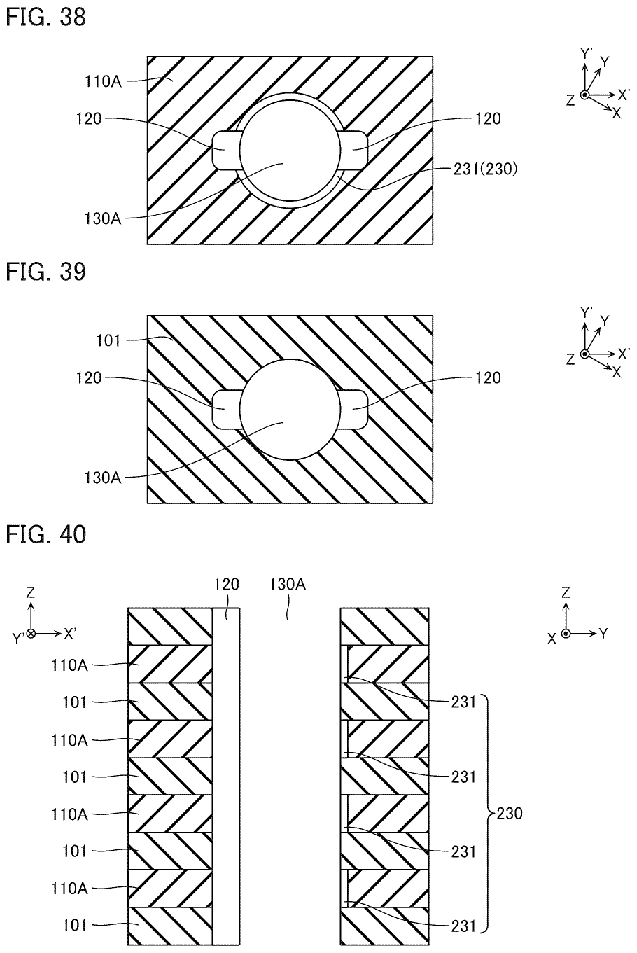

Next, for example, as illustrated in FIGS. 38 to 40, the semiconductor layer 230 is formed. For example, portions formed in the recessed portions 230A of the semiconductor layer 230B are left, and a portion formed in the opening 130A is removed. This causes the semiconductor layer 230B to be divided into a plurality of semiconductor portions 231. This process is performed by a method, such as wet etching, for example.

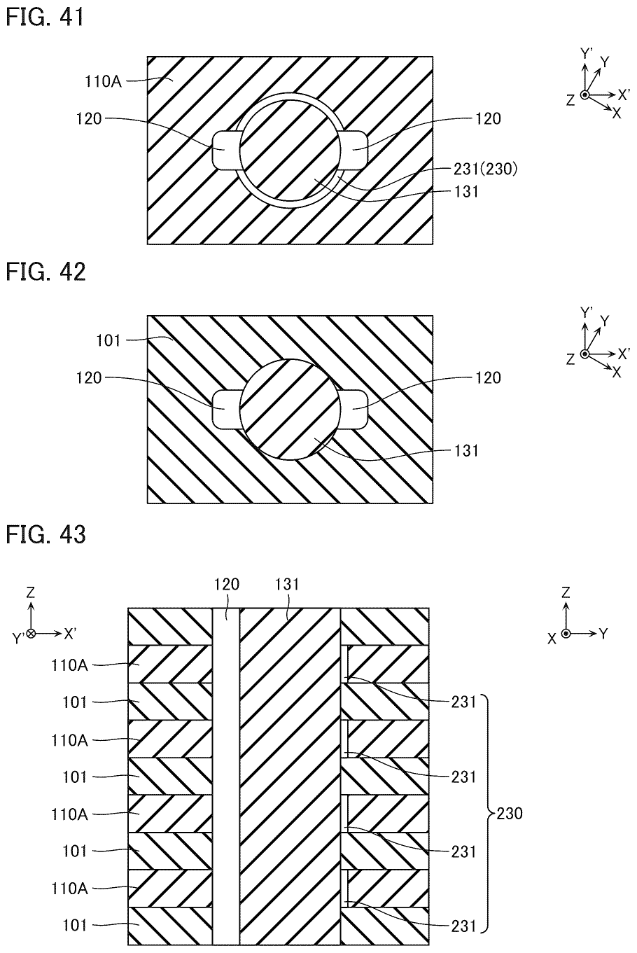

Next, for example, as illustrated in FIGS. 41 to 43, the insulating column 131 is formed inside the opening 130A. This process is performed by a method, such as CVD, for example.

Subsequently, by performing the processes described with reference to FIGS. 23 to 25 and their subsequent processes, the semiconductor memory device according to the second embodiment is formed.

### [Effect]

The semiconductor layer 130 according to the first embodiment is continuous in the Z-direction within the range in the Z-direction in which the plurality of conductive layers 110 are provided, and is opposed to the plurality of conductive layers 110 arranged in the Z-direction. With such a configuration, when accessing a certain memory cell MC, there is a possibility of disturbance occurring in other memory cells MC that are adjacent to this memory cell MC in the Z-direction.

On the other hand, the semiconductor layer 230 according to the second embodiment is divided in the Z-direction in correspondence with the plurality of conductive layers 110 arranged in the Z-direction. With such a configuration, it is possible to reduce the occurrence of the above-described disturbances in an appropriate manner.

### Third Embodiment

### [Structure]

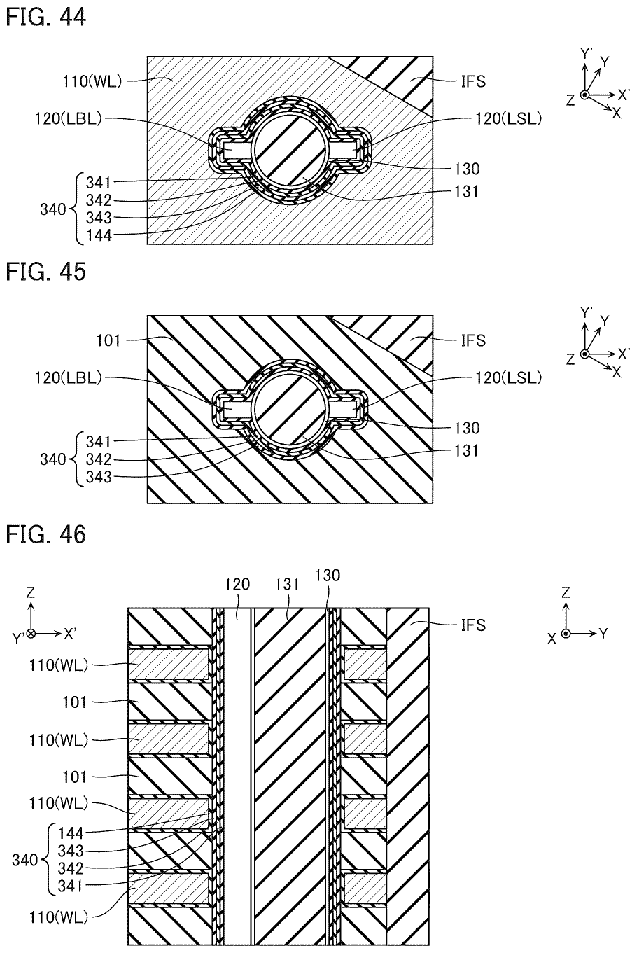

Next, referring to FIGS. 44 to 46, a semiconductor memory device according to a third embodiment is described. FIGS. 44 to 46 are schematic cross-sectional views illustrating configurations of parts of the semiconductor memory device according to the third embodiment, and each illustrates the configuration of the position corresponding to FIGS. 7 to 9. In the following description, the same reference numerals are used for the same parts as those of the semiconductor memory device according to the first embodiment, and their descriptions may be omitted.

The semiconductor memory device according to the third embodiment is basically configured similarly to the semiconductor memory device according to the first embodiment. However, the semiconductor memory device according to the third embodiment includes a gate insulating film 340 instead of the gate insulating film 140.

The gate insulating film 340 is continuous in the Z-direction within a range in the Z-direction in which the plurality of conductive layers 110 are provided, and is opposed to the plurality of conductive layers 110 arranged in the Z-direction. Therefore, as illustrated in FIGS. 44 to 46, the gate insulating film 340 is provided at the height positions corresponding to the conductive layers 110 and is also partially provided at the height positions corresponding to the insulating layers 101.

The gate insulating film 340 includes a tunnel insulating film 341, an electric charge accumulating film 342, and block insulating films 343 and 144, which are stacked between the semiconductor layer 130 and the conductive layers 110. The tunnel insulating film 341, the electric charge accumulating film 342, and the block insulating film 343 are basically configured similarly to the tunnel insulating film 141, the electric charge accumulating film 142, and the block insulating film 143. However, the tunnel insulating film 341, the electric charge accumulating film 342, and the block insulating film 343 are continuous in the Z-direction within the range in the Z-direction in which the plurality of conductive layers 110 are provided. Therefore, the tunnel insulating film 341, the electric charge accumulating film 342, and the block insulating film 343 are each provided at the height positions corresponding to the conductive layers 110 and also at the height positions corresponding to the insulating layers 101.

### [Manufacturing Method]

The semiconductor memory device according to the third embodiment is basically manufactured in the similar manner to the semiconductor memory device according to the first embodiment.

However, in the manufacturing of the semiconductor memory device according to the third embodiment, after the processes described with reference to FIGS. 11 to 13 have been performed and before the processes described with reference to FIGS. 14 to 16 will be performed, a block insulating film 343, the electric charge accumulating film 342, and the tunnel insulating film 341 are formed inside the openings 120A and 130A.

In addition, in the manufacturing of the semiconductor memory device according to the third embodiment, the tunnel insulating film 141, the electric charge accumulating film 142, and the block insulating film 143 are not formed in the process described with reference to FIGS. 28 and 29.

### Fourth Embodiment

### [Structure]

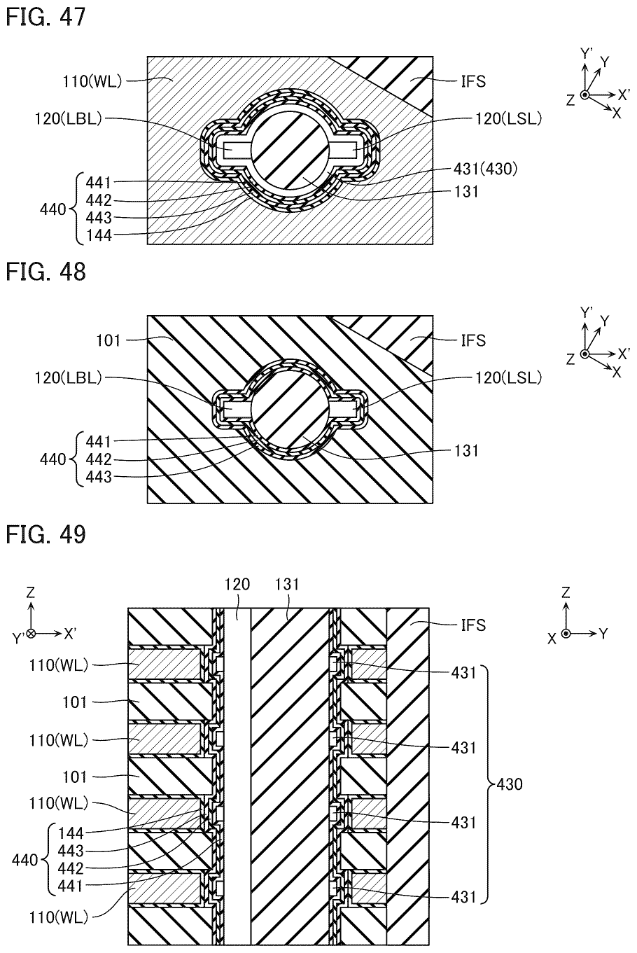

Next, referring to FIGS. 47 to 49, a semiconductor memory device according to a fourth embodiment is described. FIGS. 47 to 49 are schematic cross-sectional views illustrating configurations of parts of the semiconductor memory device according to the fourth embodiment, and each illustrate a configuration at a position corresponding to FIGS. 44 to 46. In the following description, the same reference numerals are used for the same parts as those of the semiconductor memory device according to the third embodiment, and their descriptions may be omitted.

The semiconductor memory device according to the fourth embodiment basically configured similarly to the semiconductor memory device according to the third embodiment. However, the semiconductor memory device according to the fourth embodiment includes a semiconductor layer 430 and a gate insulating film 440 instead of the semiconductor layer 130 and the gate insulating film 340.

The semiconductor layer 430 is divided in the Z-direction in correspondence with the plurality of conductive layers 110 arranged in the Z-direction. In other words, as illustrated in FIGS. 47 and 49, the semiconductor layer 430 is provided at the height positions corresponding to the conductive layers 110. However, as illustrated in FIGS. 48 and 49, the semiconductor layer 430 is not provided at any of the height positions corresponding to the insulating layers 101. Parts of the semiconductor layer 430 divided in the Z-direction are referred to as semiconductor portions 431.

Each of the semiconductor portions 431 is opposed to one corresponding conductive layer 110. The semiconductor portion 431 contains, for example, polycrystalline silicon (Si) and the like. Each of the semiconductor portions 431 functions as a channel region of a memory cell MC.

The gate insulating film 440 includes a tunnel insulating film 441, an electric charge accumulating film 442, and block insulating films 443 and 144, which are stacked between the semiconductor layer 430 and the conductive layers 110. The tunnel insulating film 441, the electric charge accumulating film 442, and the block insulating film 443 are basically configured similarly to the tunnel insulating film 341, the electric charge accumulating film 342, and the block insulating film 343. However, each of the tunnel insulating film 441, the electric charge accumulating film 442, and the block insulating film 443 has a plurality of projecting portions arranged in the Z-direction in correspondence with the plurality of semiconductor portions 431 arranged in the Z-direction and protruding toward a conductive layer 110 side. In other words, each of the tunnel insulating film 441, the electric charge accumulating film 442, and the block insulating film 443 is formed along an unevenness including the plurality of semiconductor portions 431 arranged in the Z-direction, the outer peripheral surfaces of the conductor columns 120, and the outer peripheral surface of the insulating column 131.

For example, in the example illustrated in FIG. 47, the insulating column 131 is provided between the pair of conductor columns 120, and is in contact with the pair of conductor columns 120. In the X-Y cross-section illustrated in FIG. 47, the outer peripheral surface of the insulating column 131 is formed approximately along a circle. The pair of conductor columns 120 are provided outside this circle. The length in the Y′-direction of the conductor column 120 is smaller than the diameter of the circle along the outer peripheral surface of the insulating column 131. A surface on the other conductor column 120 side in the X′-direction of one conductor column 120 is in contact with the insulating column 131. Similarly, a surface on the one conductor column 120 side in the X′-direction of the other conductor column 120 is in contact with the insulating column 131.

The semiconductor portion 431 is formed along the outer peripheral surfaces of the pair of conductor columns 120 and the insulating column 131 in the X-Y cross-section illustrated in FIG. 47. In other words, a portion other than the contact surfaces with the pair of conductor columns 120 of the outer peripheral surfaces of the insulating column 131 is in contact with the semiconductor portion 431. In addition, a portion other than the contact surface with the insulating column 131 of the outer peripheral surface of the conductor column 120 (the surface on a side opposite to the other conductor column 120 in the X′-direction, and both surfaces in the Y′-direction) is in contact with the semiconductor portion 431. An outer peripheral surface of a portion provided on the outer peripheral surface of the insulating column 131 of the semiconductor portions 431 is formed approximately along a circle. The pair of conductor columns 120 are provided mainly on the outside of this circle, but each also has a portion provided on the inside of this circle. In addition, the gate insulating film 440 is formed along an outer peripheral surface of the semiconductor portion 431. The conductive layer 110 surrounds the semiconductor portion 431 via the gate insulating film 440.

### [Manufacturing Method]

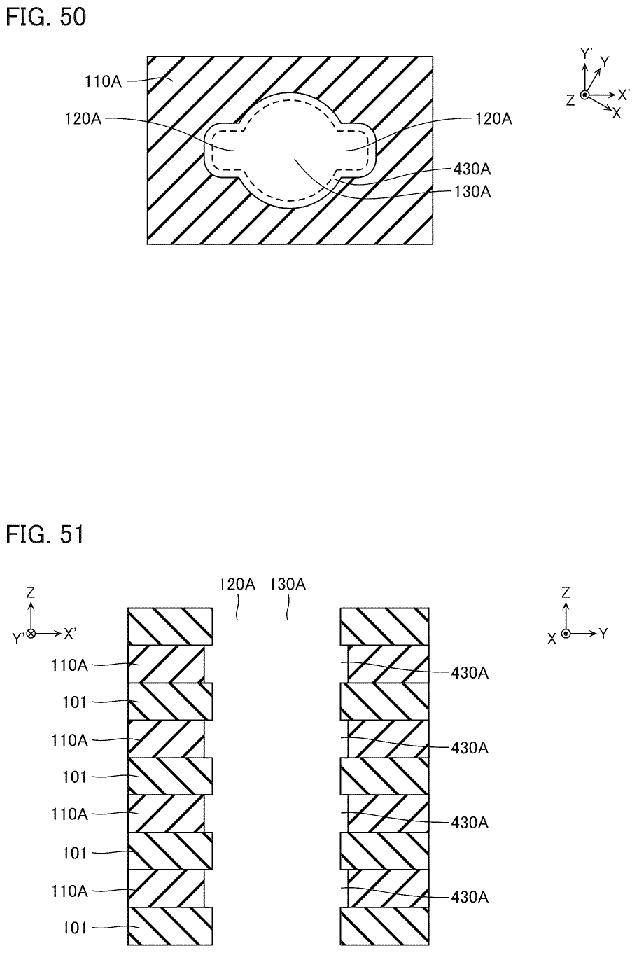

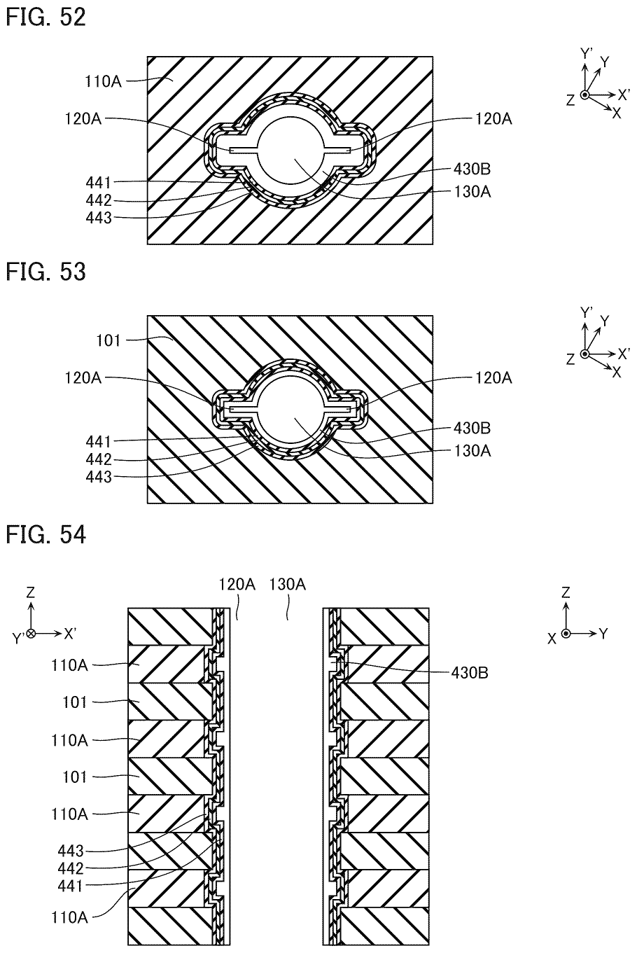

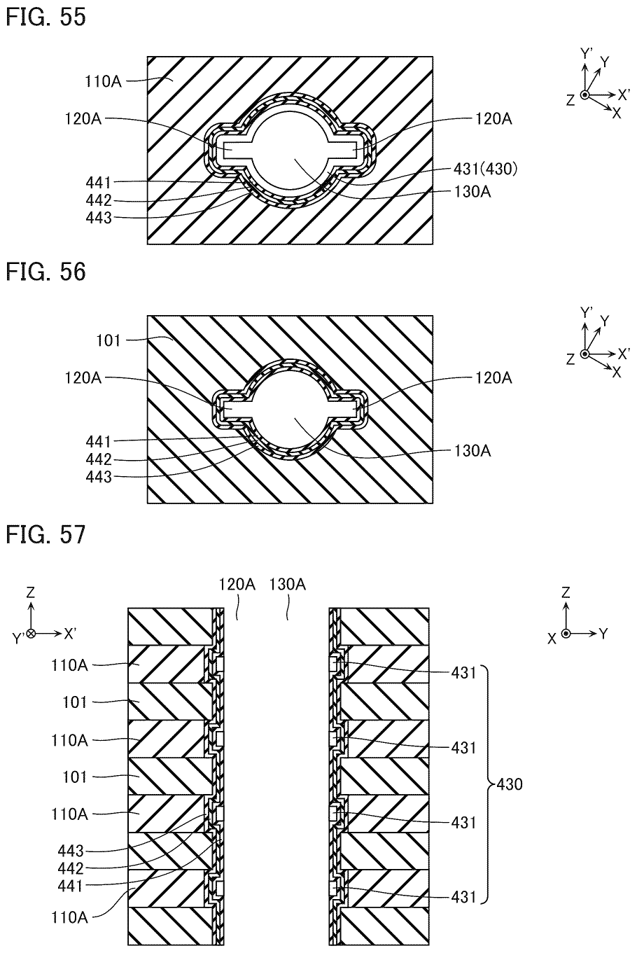

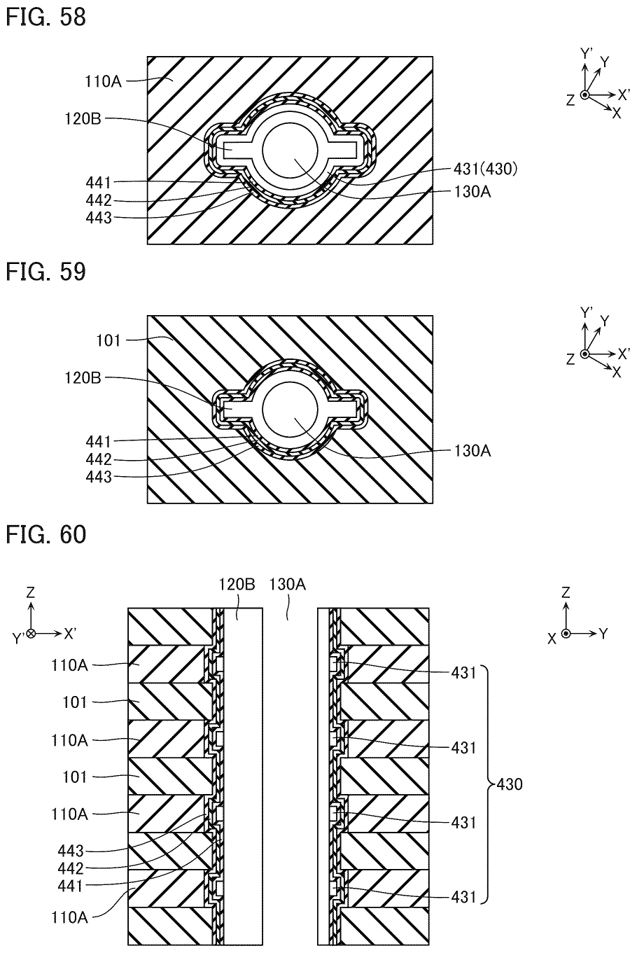

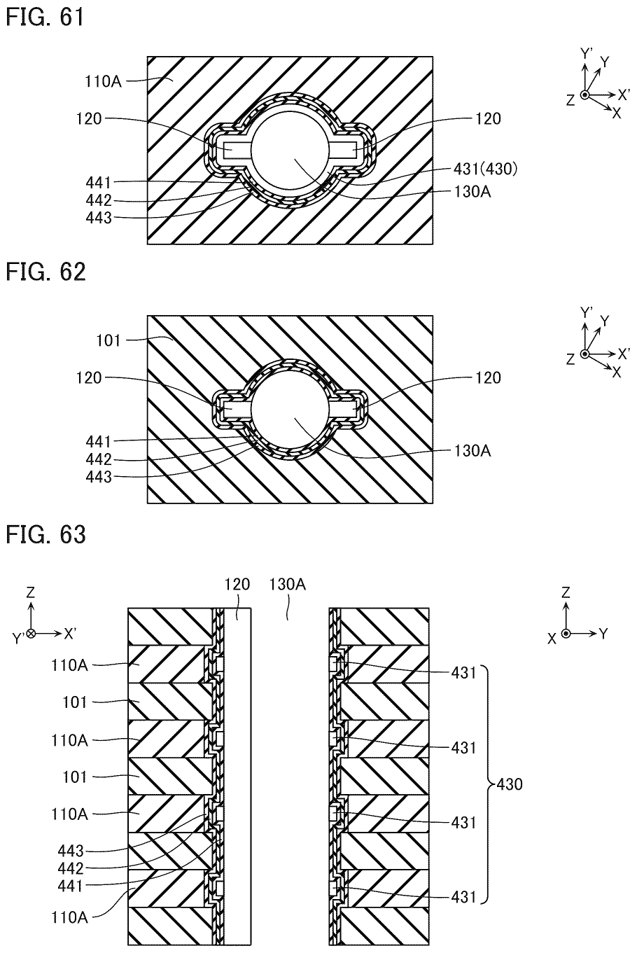

Next, referring to FIGS. 50 to 63, a manufacturing method of the semiconductor memory device according to the fourth embodiment is described. FIG. 50 to FIG. 63 are schematic cross-sectional views for describing the manufacturing method. FIGS. 50, 52, 55, 58, and 61 illustrate cross-sections corresponding to FIG. 47. FIGS. 53, 56, 59, and 62 illustrate cross-sections corresponding to FIG. 48. FIGS. 51, 54, 57, 60, and 63 illustrate cross-sections corresponding to FIG. 49.

In manufacturing the semiconductor memory device according to the fourth embodiment, for example, the processes up to the processes described with reference to FIGS. 11 to 13 in the manufacturing method of the semiconductor memory device according to the first embodiment are performed.

Next, as illustrated in FIGS. 50 and 51, portions of the sacrifice layers 110A are removed inside the openings 120A and 130A to form recessed portions 430A. This process is performed, for example, by wet etching.

Next, as illustrated in FIGS. 52 to 54, a block insulating film 443, the electric charge accumulating film 442, the tunnel insulating film 441, and a semiconductor layer 430B are formed inside the openings 120A and 130A and the recessed portions 430A. The block insulating film 443, the electric charge accumulating film 442, and the tunnel insulating film 441 have the unevenness along the plurality of recessed portions 430A arranged in the Z-direction. A contact surface of the semiconductor layer 430B with the tunnel insulating film 441 is formed along the unevenness formed in the tunnel insulating film 441. On the other hand, an exposed surface to the openings 120A and 130A of the semiconductor layer 430B does not have such unevenness. The semiconductor layer 430B is formed with a thickness such that the openings 120A and 130A is not filled. This process is performed by a method, such as CVD, for example.

Next, for example, as illustrated in FIGS. 55 to 57, the semiconductor layer 430 is formed. For example, portions formed in the recessed portions of the tunnel insulating film 441 of the semiconductor layer 430B are left, and the other portion is removed. This causes the semiconductor layer 430B to be divided into the plurality of semiconductor portions 431. This process is performed by a method, such as wet etching, for example.

Next, as illustrated in FIGS. 58 to 60, for example, the conductor layer 120B is formed inside the openings 120A and 130A. The conductor layer 120B is formed with a thickness that is sufficient to fill the openings 120A, but not to fill the opening 130A. This process is performed by a method, such as CVD, for example.

Next, for example, as illustrated in FIGS. 61 to 63, the conductor columns 120 are formed. For example, the portions formed in the openings 120A of the conductor layer 120B are left, and the portion formed in the opening 130A is removed. This process is performed by a method, such as wet etching, for example.

Next, the insulating column 131 is formed inside the opening 130A. This process is performed by a method, such as CVD, for example.

Subsequently, for example, in the manufacturing method of the semiconductor memory device according to the first embodiment, the process described with reference to FIGS. 23 to 25 and its subsequent processes are performed. However, in the process described with reference to FIGS. 28 and 29, the tunnel insulating film 141, the electric charge accumulating film 142, and the block insulating film 143 are not formed. This forms the semiconductor memory device according to the fourth embodiment.

### [Effect]

The semiconductor layer 430 according to the fourth embodiment is divided in the Z-direction in correspondence with the plurality of conductive layers 110 arranged in the Z-direction, similarly to the semiconductor layer 230 according to the second embodiment. With such a configuration, it is possible to reduce the occurrence of the above-described disturbances in the appropriate manner.

### Fifth Embodiment

### [Structure]

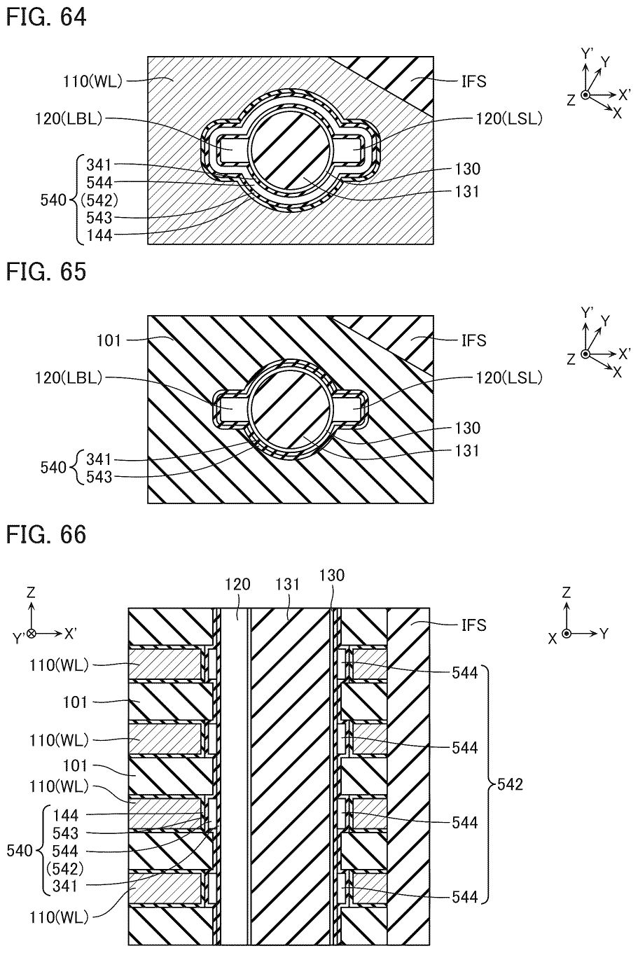

Next, referring to FIGS. 64 to 66, a semiconductor memory device according to a fifth embodiment is described. FIGS. 64 to 66 are schematic cross-sectional views illustrating configurations of parts of the semiconductor memory device according to the fifth embodiment, and each illustrate a configuration at a position corresponding to FIGS. 44 to 46. In the following description, the same reference numerals are used for the same parts as those of the semiconductor memory device according to the third embodiment, and their descriptions may be omitted.

The semiconductor memory device according to the fifth embodiment is basically configured similarly to the semiconductor memory device according to the third embodiment. However, the semiconductor memory device according to the fifth embodiment includes a gate insulating film 540 instead of the gate insulating film 340.

The gate insulating film 540 includes a tunnel insulating film 341, an electric charge accumulating film 542, and block insulating films 543 and 144, which are stacked between the semiconductor layer 130 and the conductive layer 110.

The electric charge accumulating film 542 is divided in the Z-direction in correspondence with the plurality of conductive layers 110 arranged in the Z-direction. In other words, as illustrated in FIGS. 64 and 66, the electric charge accumulating film 542 is provided at the height positions corresponding to the conductive layers 110. However, as illustrated in FIGS. 65 and 66, the electric charge accumulating film 542 is not provided at any of the height positions corresponding to the insulating layers 101. Parts of the electric charge accumulating film 542 divided in the Z-direction are referred to as electric charge accumulating portions 544.

Each of the electric charge accumulating portions 544 is opposed to one corresponding conductive layer 110. The electric charge accumulating portion 544 contains, for example, polycrystalline silicon containing impurities such as phosphorus (P) or boron (B). Each of the electric charge accumulating portions 544 is a conductive floating gate that can charge the amount of electric charge corresponding to the data stored in the memory cell MC.

The block insulating film 543 is basically configured similarly to the block insulating film 343. However, the block insulating film 543 has a plurality of projecting portions arranged in the Z-direction in correspondence with the plurality of electric charge accumulating portions 544 arranged in the Z-direction and protruding toward a conductive layer 110 side. In other words, the block insulating film 543 is formed along an unevenness including the plurality of electric charge accumulating portions 544 arranged in the Z-direction and an outer peripheral surface of the tunnel insulating film 341.

The X-Y cross-section illustrated in FIG. 64 is almost the same as the X-Y cross-section described with reference to FIG. 7. However, in FIG. 64, the gate insulating film 540 is illustrated instead of the gate insulating film 140.

### [Manufacturing Method]

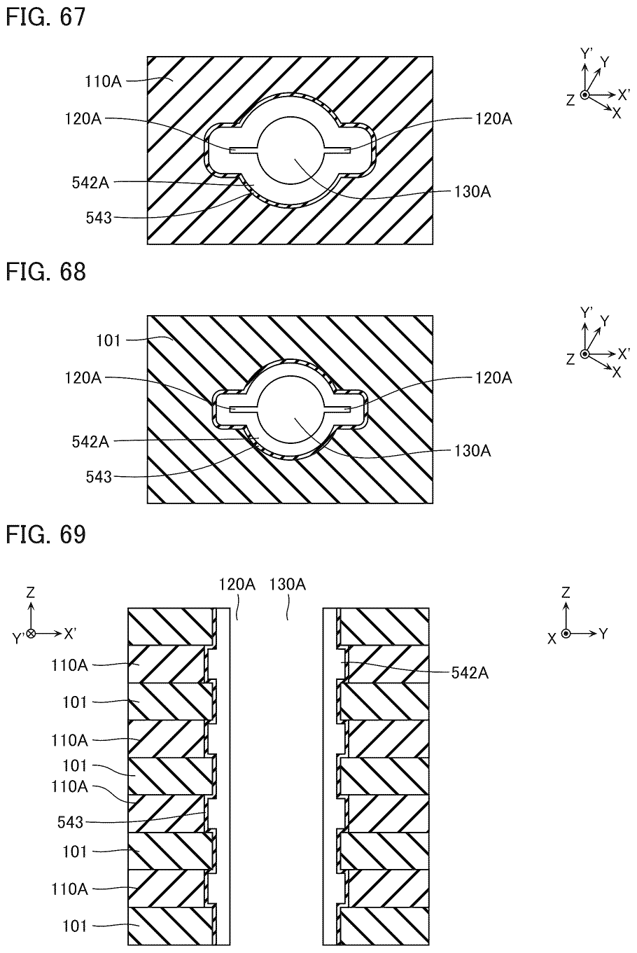

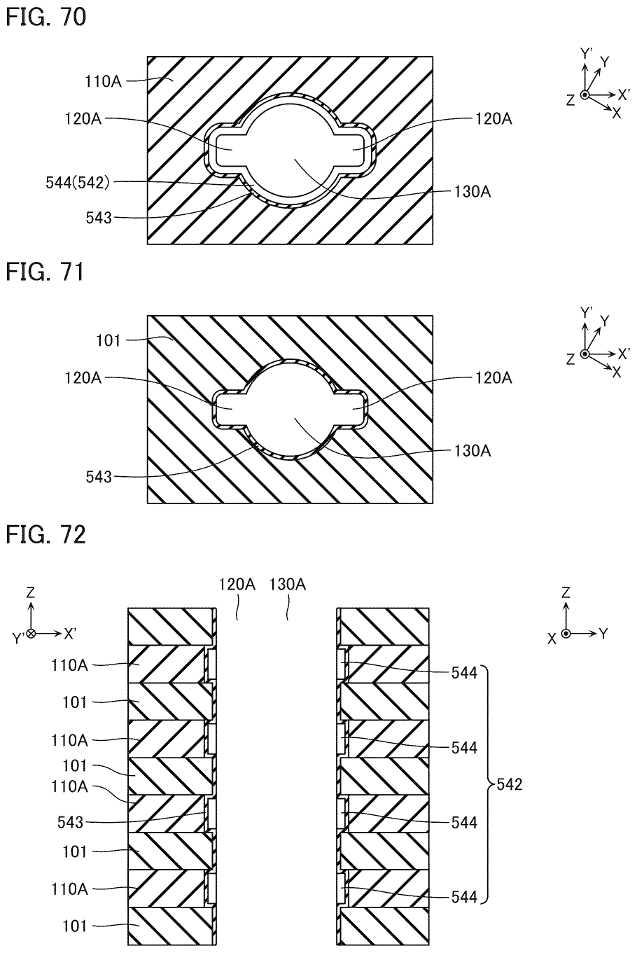

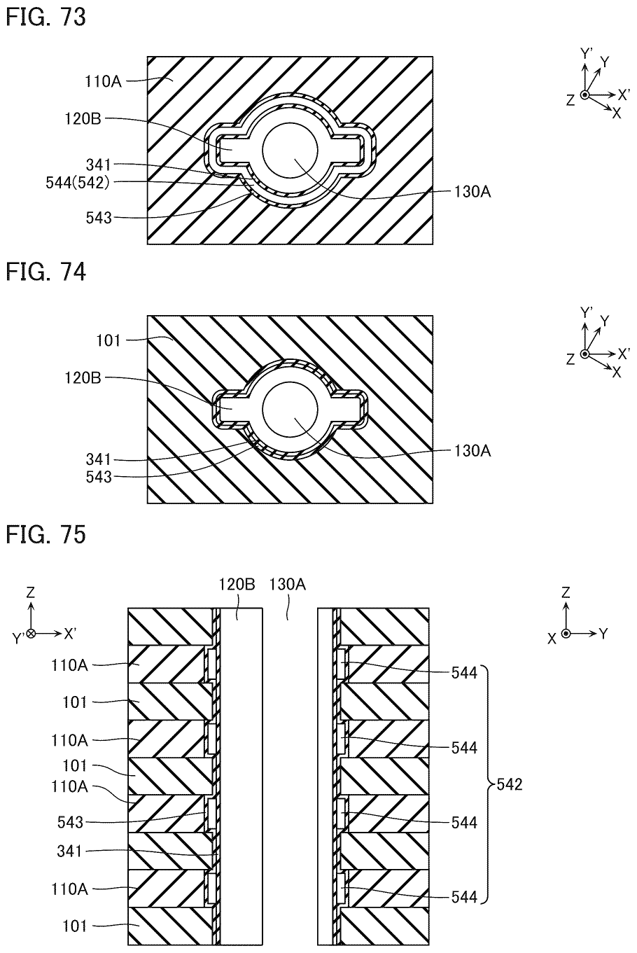

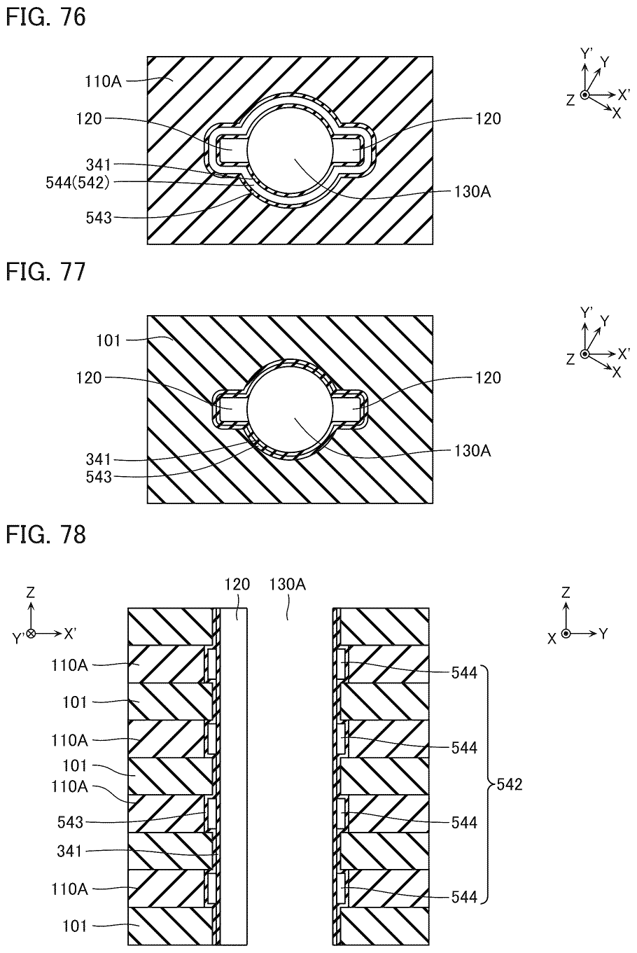

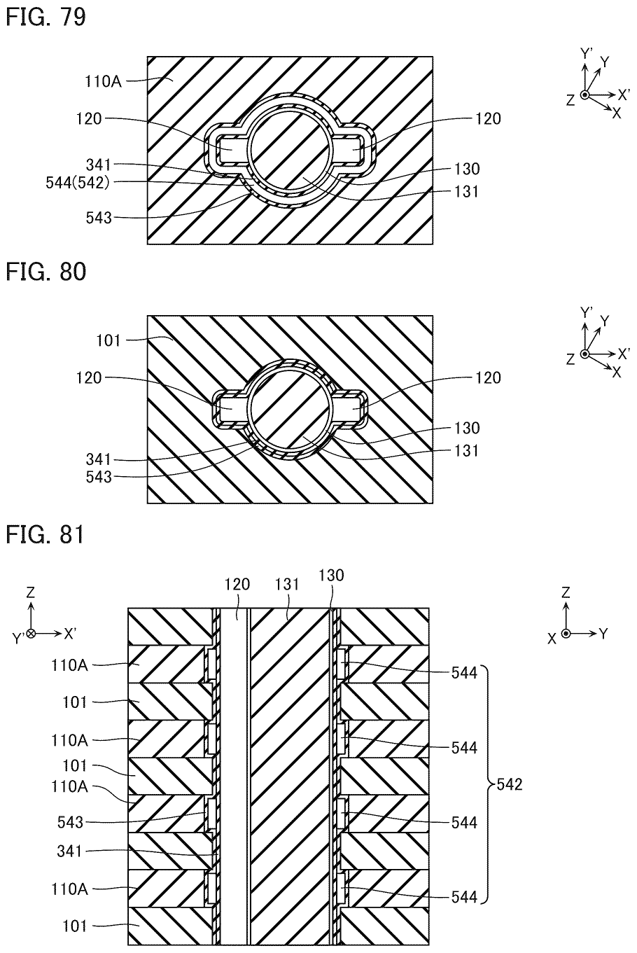

Next, referring to FIGS. 67 to 81, a manufacturing method of the semiconductor memory device according to the fifth embodiment is described. FIG. 67 to FIG. 81 are schematic cross-sectional views for describing the manufacturing method. FIGS. 67, 70, 73, 76, and 79 illustrate cross-sections corresponding to FIG. 64. FIGS. 68, 71, 74, 77, and 80 illustrate cross-sections corresponding to FIG. 65. FIGS. 69, 72, 75, 78, and 81 illustrate cross-sections corresponding to FIG. 66.

In manufacturing the semiconductor memory device according to the fifth embodiment, for example, the processes up to the processes described with reference to FIGS. 50 and 51 in the manufacturing method of the semiconductor memory device according to the fourth embodiment are performed.

Next, as illustrated in FIGS. 67 to 69, the block insulating film 543 and a semiconductor layer 542A are formed inside the openings 120A and 130A and the recessed portions 430A. The semiconductor layer 542A is formed with a thickness that is sufficient to fill the recessed portions 430A, but not to fill the openings 120A and 130A. This process is performed by a method, such as CVD, for example.

Next, the electric charge accumulating film 542 is formed, as illustrated in FIGS. 70 to 72, for example. For example, portions formed in the recessed portions 430A of the semiconductor layer 542A are left, and a portion formed in the openings 120A and 130A is removed. This causes the semiconductor layer 542A to be divided into a plurality of electric charge accumulating portions 544. This process is performed by a method, such as wet etching, for example.

Next, as illustrated in FIGS. 73 to 75, for example, the tunnel insulating film 341 and the conductor layer 120B are formed inside the openings 120A and 130A. The conductor layer 120B is formed with a thickness that is sufficient to fill the opening 120A, but not to fill the opening 130A. This process is performed by a method, such as CVD, for example.

Next, for example, as illustrated in FIGS. 76 to 78, the conductor columns 120 are formed. For example, the portions formed in the openings 120A of the conductor layer 120B are left, and the portion formed in the opening 130A is removed. This process is performed by a method, such as wet etching, for example.

Next, the semiconductor layer 130 and the insulating column 131 are formed inside the opening 130A. This process is performed by a method, such as CVD, for example.

Subsequently, for example, the process described with reference to FIGS. 23 to 25 and its subsequent processes in the manufacturing method of the semiconductor memory device according to the first embodiment are performed. However, in the processes described with reference to FIGS. 28 and 29, the tunnel insulating film 141, the electric charge accumulating film 142, and the block insulating film 143 are not formed. This forms the semiconductor memory device according to the fifth embodiment.

### [Effect]

The electric charge accumulating film 142 according to the first embodiment and the electric charge accumulating film 342 according to the third embodiment are continuous in the Z-direction within a range in the Z-direction in which the plurality of conductive layers 110 are provided. On the other hand, the electric charge accumulating film 542 according to the fifth embodiment is divided in the Z-direction in correspondence with the plurality of conductive layers 110 arranged in the Z-direction. With such a configuration, a conductive floating gate can be employed as the electric charge accumulating portion 544 of the memory cell MC.

### Sixth Embodiment

### [Structure]

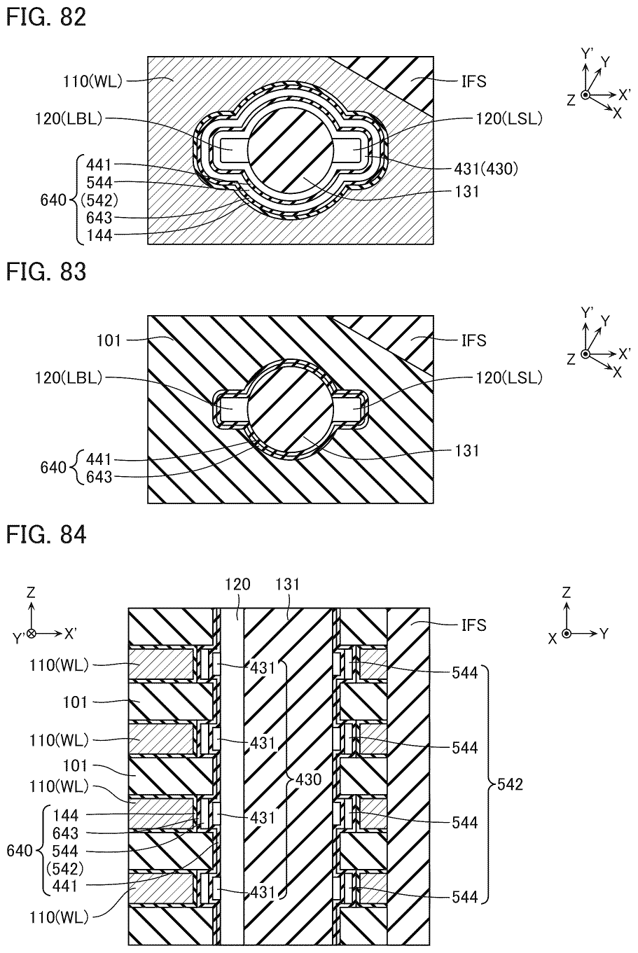

Next, referring to FIGS. 82 to 84, a semiconductor memory device according to a sixth embodiment is described. FIGS. 82 to 84 are schematic cross-sectional views illustrating configurations of parts of the semiconductor memory device according to the sixth embodiment, and each illustrates the configuration of the position corresponding to FIGS. 64 to 66. In the following description, the same reference numerals are used for the same parts as those of the semiconductor memory device according to the fifth embodiment, and their descriptions may be omitted.

The semiconductor memory device according to the sixth embodiment is basically configured similarly to the semiconductor memory device according to the fifth embodiment. However, the semiconductor memory device according to the sixth embodiment includes the semiconductor layer 430 and a gate insulating film 640 instead of the semiconductor layer 130 and the gate insulating film 540.

The gate insulating film 640 is basically configured similarly to the gate insulating film 540. However, the gate insulating film 640 includes the tunnel insulating film 441 and a block insulating film 643 instead of the tunnel insulating film 341 and the block insulating film 543.

The block insulating film 643 is basically configured similarly to the block insulating film 543. The block insulating film 643 is formed along the unevenness including the plurality of electric charge accumulating portions 544 arranged in the Z-direction and the outer peripheral surface of the tunnel insulating film 441.

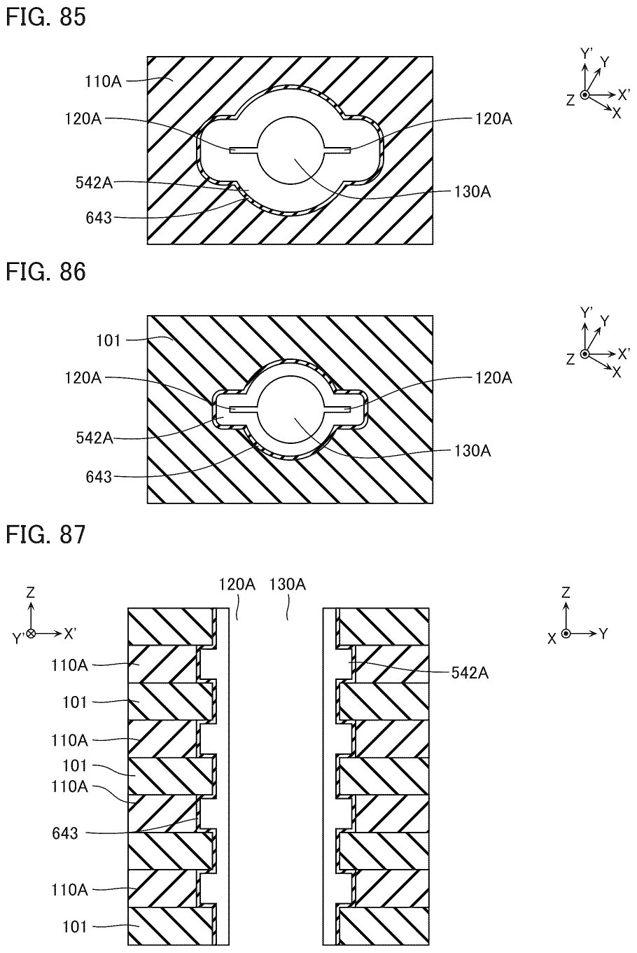

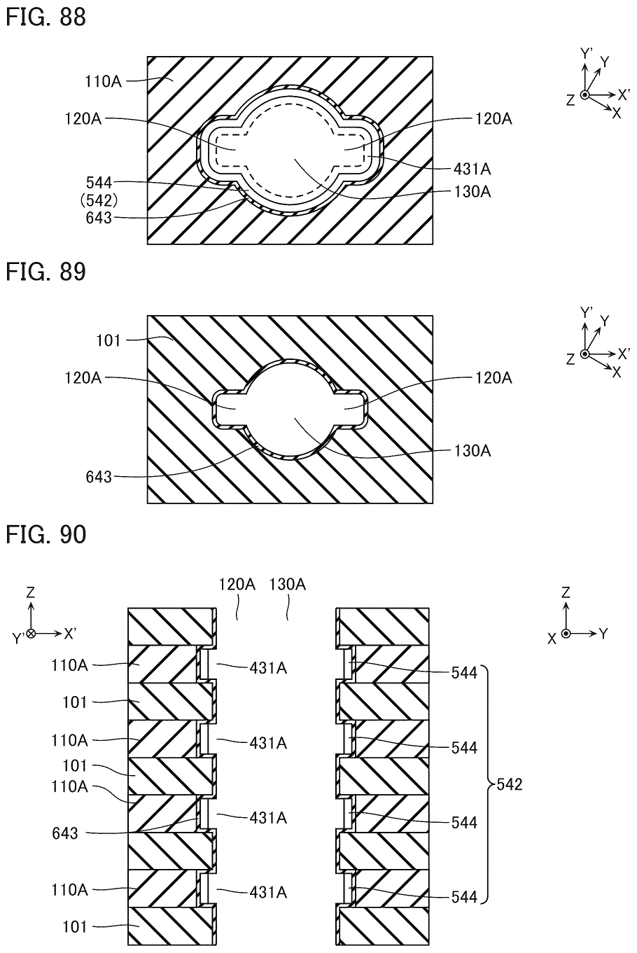

The X-Y cross-section illustrated in FIG. 82 is almost the same as the X-Y cross-section described with reference to FIG. 47. However, in FIG. 82, the gate insulating film 640 is illustrated instead of the gate insulating film 440.

[Manufacturing Method]Next, referring to FIGS. 85 to 96, a manufacturing method of the semiconductor memory device according to the sixth embodiment is described. FIG. 85 to FIG. 96 are schematic cross-sectional views for describing the manufacturing method. FIGS. 85, 88, 91, and 94 illustrate cross-sections corresponding to FIG. 82. FIGS. 86, 89, 92, and 95 illustrate cross-sections corresponding to FIG. 83. FIGS. 87, 90, 93, and 96 illustrate cross-sections corresponding to FIG. 84.

In manufacturing the semiconductor memory device according to the sixth embodiment, for example, the processes up to the process described with reference to FIGS. 50 and 51 in the manufacturing method of the semiconductor memory device according to the fourth embodiment are performed.

Next, as illustrated in FIGS. 85 to 87, the block insulating film 643 and the semiconductor layer 542A are formed inside the openings 120A and 130A and the recessed portions 430A. The semiconductor layer 542A is formed with a thickness that is sufficient to fill the recessed portions 430A, but not to fill the openings 120A and 130A. This process is performed by a method, such as CVD, for example.

Next, as illustrated in FIGS. 88 to 90, a portion of the semiconductor layer 542A is removed inside the openings 120A and 130A, and recessed portions 431A are formed along with the electric charge accumulating film 542. The recessed portions 431A are formed by partially removing the portions formed in the recessed portions 430A (FIGS. 50 and 51) of the semiconductor layer 542A and leaving the other portions formed in the recessed portions 430A of the semiconductor layer 542A. The recessed portion 431A is formed with an upper surface of a portion of the block insulating film 643 formed on an upper surface of the insulating layer 101, a lower surface of a portion of the block insulating film 643 formed on a lower surface of the insulating layer 101, and an exposed surface to the openings 120A and 130A of the electric charge accumulating portion 544. This process is performed by wet etching, for example.

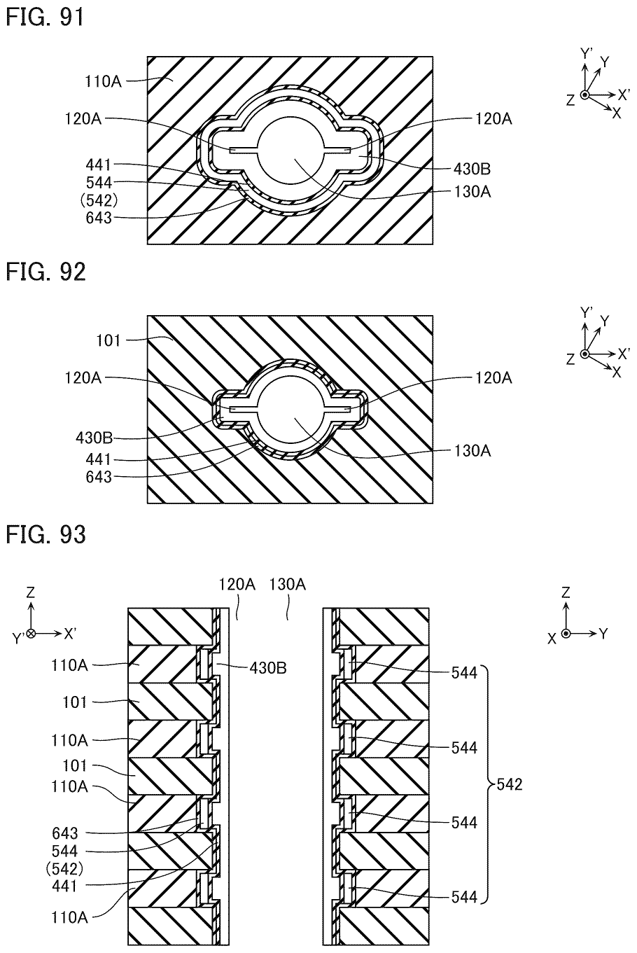

Next, as illustrated in FIGS. 91 to 93, the tunnel insulating film 441 and the semiconductor layer 430B are formed inside the openings 120A and 130A and the recessed portions 431A. The tunnel insulating film 441 has an unevenness along the plurality of recessed portions 431A arranged in the Z-direction. The contact surface of the semiconductor layer 430B with the tunnel insulating film 441 is formed along the unevenness formed on the tunnel insulating film 441. On the other hand, an exposed surface to the openings 120A and 130A of the semiconductor layer 430B does not have such unevenness. The semiconductor layer 430B is formed with a thickness such that the openings 120A and 130A are not filled. This process is performed by a method, such as CVD, for example.

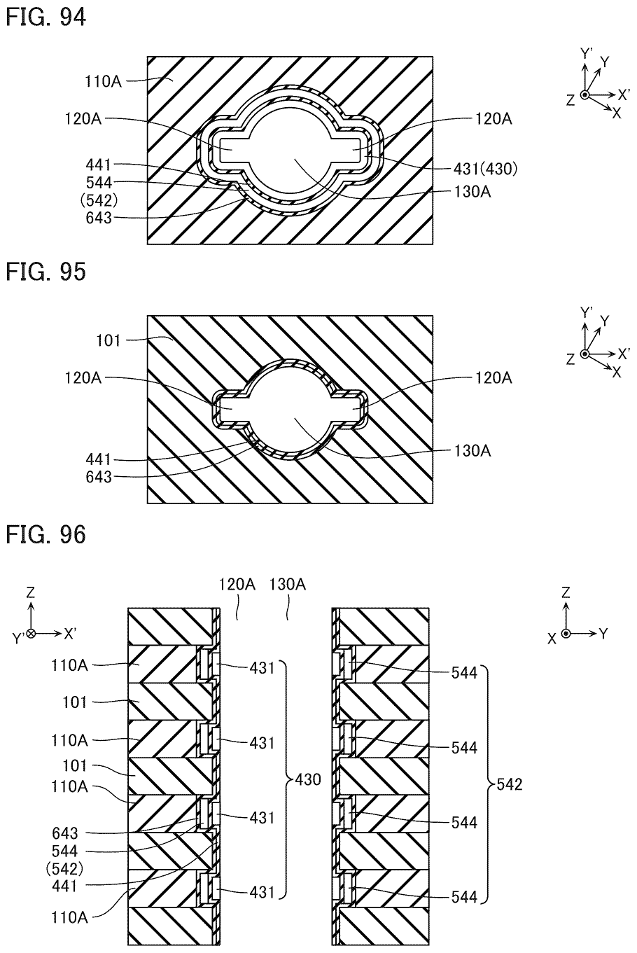

Next, for example, as illustrated in FIGS. 94 to 96, the semiconductor layer 430 is formed. For example, portions formed in recessed portions of the tunnel insulating film 441 along the recessed portions 431A of the semiconductor layer 430B are left, and the other portion is removed. This causes the semiconductor layer 430B to be divided into the plurality of semiconductor portions 431. This process is performed by a method, such as wet etching, for example.

Subsequently, for example, the processes described with reference to FIGS. 58 to 60 and their subsequent processes in the manufacturing method of the semiconductor memory device according to the fourth embodiment are performed. This forms the semiconductor memory device according to the sixth embodiment.

### [Effect]

The semiconductor layer 430 according to the sixth embodiment is divided in the Z-direction in correspondence with the plurality of conductive layers 110 arranged in the Z-direction, similarly to the semiconductor layer 430 of the fourth embodiment. With such a configuration, it is possible to reduce the occurrence of the above-described disturbances in the appropriate manner.

### [Modifications of First Embodiment to Sixth Embodiment]

The configurations of the semiconductor memory device according to the first embodiment to the sixth embodiment have been described. However, the configurations described above are merely examples, and the specific configurations can be adjusted as appropriate.

For example, in the first embodiment to the sixth embodiment, the inner peripheral surface and an outer peripheral surface of the semiconductor layer 130 and the like are formed approximately along the circle in the X-Y cross-section, or include a portion formed approximately along the circle. However, the inner peripheral surface and the outer peripheral surface of the semiconductor layer 130 and the like do not have to be formed in a circular shape, but formed approximately along an elliptical or oval shape, or may include a portion formed approximately along an elliptical or oval shape.

For example, the gate insulating film (memory film) according to the first embodiment to the sixth embodiment may include a ferroelectric film or the like instead of the electric charge accumulating film 142 and the like.

The ferroelectric film described herein may contain, for example, orthorhombic hafnium oxide. The hafnium oxide contained in the ferroelectric film may mainly contain orthorhombic crystals. More specifically, the hafnium oxide contained in the ferroelectric film may mainly contain a third orthorhombic crystal (orthorhombic III (space group Pbc21, space group number 29). Among crystals in the hafnium oxide contained in the ferroelectric film, a proportion of the orthorhombic crystals may be the largest. The orthorhombic crystal is also known as a rhombic crystal.

In addition, the ferroelectric film described herein can contain at least one additive element selected from the group consisting of silicon (Si), zirconium (Zr), aluminum (Al), yttrium (Y), strontium (Sr), lanthanum (La), samarium (Sm), gadolinium (Gd), terbium (Tb), dysprosium (Dy), holmium (Ho), erbium (Er), ytterbium (Yb), lutetium (Lu), and barium (Ba).

From the aspect of causing the hafnium oxide to exhibit ferroelectricity, a concentration of the additive element is preferably 0.1 atomic percent or more and 60 atomic percent or less. The appropriate range of the concentration of the additive element to cause the hafnium oxide to exhibit the ferroelectricity differs depending on the kind of the additive element. For example, in the case of the additive element being silicon (Si), the appropriate range of the concentration of the additive element to exhibit the ferroelectricity is 3 atomic percent or more and 7 atomic percent or less. For example, in the case of the additive element being barium (Ba), the appropriate range of the concentration of the additive element to exhibit the ferroelectricity is 0.1 atomic percent or more and 3 atomic percent or less. For example, in the case of the additive element being zirconium (Zr), the appropriate range of the concentration of the additive element to exhibit the ferroelectricity is 10 atomic percent or more and 60 atomic percent or less.

For example, in the semiconductor memory device according to the first embodiment, as described with reference to FIG. 7 and the like, the semiconductor layer 130 is provided between the pair of conductor columns 120. In addition, the surface on the other conductor column 120 side in the X′-direction of the one conductor column 120, and the surface on the one conductor column 120 side in the X′-direction of the other conductor column 120 are in contact with the semiconductor layer 130. This type of structure is achieved by forming the semiconductor layer 130 after forming the conductor columns 120, as described with reference to FIGS. 14 to 22, for example. The same applies to the semiconductor memory device according to the third embodiment (FIG. 44) and the semiconductor memory device according to the fifth embodiment (FIG. 64).

On the other hand, in the semiconductor memory device according to the second embodiment, as described with reference to FIG. 30, the semiconductor portion 231 is formed along the outer peripheral surface of the insulating column 131 and is divided in the Y′-direction via the pair of conductor columns 120. This type of structure is achieved by, for example, removing portions of the sacrifice layers 110A after forming the conductor column 120, and then removing a portion of the semiconductor layer 230B after forming the semiconductor layer 230B, thereby dividing the semiconductor layer 230B in the Z-direction, as described with reference to FIGS. 33 to 40.

Furthermore, in the semiconductor memory device according to the fourth embodiment, as described with reference to FIG. 47, the semiconductor portion 431 is formed along the outer peripheral surfaces of the pair of conductor columns 120 and the insulating column 131. This type of structure is achieved by, for example, forming the conductor columns 120 after forming the semiconductor portion 431, as described with reference to FIGS. 52 to 63. The same applies to the semiconductor memory device according to the sixth embodiment (FIG. 82).

For example, in the first embodiment, the second embodiment, the third embodiment, and the fifth embodiment, the conductor columns 120 may be formed after forming the semiconductor layer 130 and the like. When such a method is employed in the first embodiment to the third embodiment, the memory pillar MP will have the X-Y cross-section as described with reference to FIG. 47 at the height position corresponding to the conductive layer 110. In addition, when such a method is employed in the fifth embodiment, the memory pillar MP will have the X-Y cross-section as described with reference to FIG. 82 at the height position corresponding to the conductive layer 110.

### Seventh Embodiment

In the first embodiment to the sixth embodiment and their modifications, the openings 120A and 130A is formed in the process described with reference to FIGS. 11 to 13. This process is intended to be performed by patterning using, for example, a mask having a pattern of the openings 120A and 130A, and forming the openings 120A and the opening 130A simultaneously by, for example, RIE.

However, depending on conditions of the RIE, when the openings 120A and the opening 130A are formed simultaneously, the corners at boundary portions between the openings 120A and the opening 130A may become rounded, and there is a possibility that the openings 120A and 130A is not formed properly.

Therefore, according to the embodiment, the openings 120A and the opening 130A are formed separately. This makes it possible to form each of the openings 120A and the opening 130A in an appropriate manner.

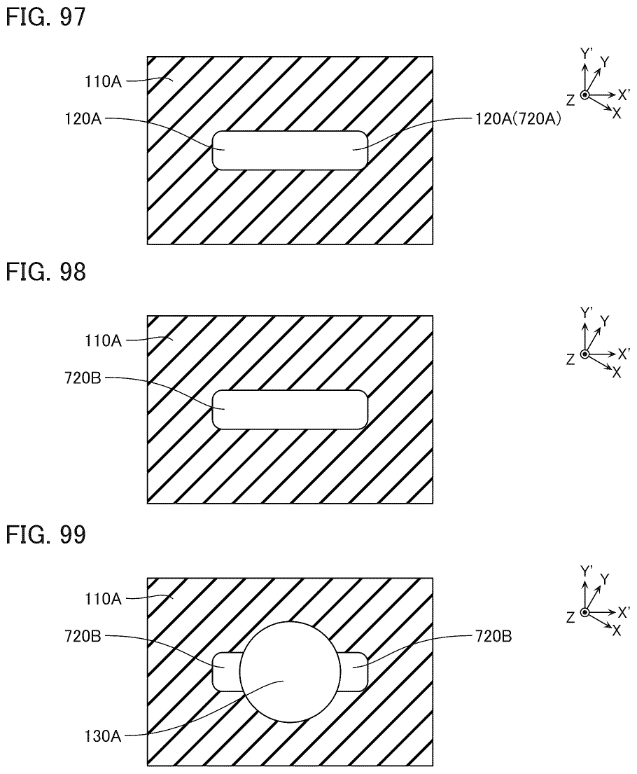

FIGS. 97 to FIG. 99 are schematic cross-sectional views for describing a manufacturing method of a semiconductor memory device according to a seventh embodiment. FIGS. 97 to 99 illustrate cross-sections corresponding to FIG. 7.

In the manufacturing method of the semiconductor memory device according to the seventh embodiment, the processes up to the process described with reference to FIG. 10 in the manufacturing method of the semiconductor memory device according to the first embodiment are performed.

Next, for example, as illustrated in FIG. 97, an opening 720A is formed. The opening 720A is formed in a shape of an approximately elongated rectangle extending in the X′-direction when viewed in the Z-direction. Each of one end portion and the other end portion in the X′-direction of the opening 720A constitutes the opening 120A. This process is performed, for example, by RIE.

Next, as illustrated in FIG. 98, for example, a sacrifice layer 720B is formed inside the opening 720A, from material such as silicon (Si), silicon oxide (SiO₂) added with impurities such as phosphorus (P), boron (B), or the like, silicon nitride (Si₃N₄), or the like. This process is performed by a method, such as CVD, for example.

Next, for example, as illustrated in FIG. 99, the opening 130A is formed. This process is performed, for example, by RIE.

Next, by removing the sacrifice layer 720B through the opening 130A, the structure as illustrated in FIGS. 11 to 13 is formed.

Subsequently, the processes described with reference to FIGS. 14 to 16 and their subsequent processes in the manufacturing method of the semiconductor memory device according to the first embodiment are performed. This forms the semiconductor memory device according to the first embodiment.

In the examples of FIGS. 97 to 99, the opening 720A is formed, the sacrifice layer 720B is formed inside the opening 720A, and then the opening 130A is formed. However, for example, it is also possible to form the opening 130A, form the sacrifice layer inside the opening 130A, and then form the opening 720A.

In addition, the manufacturing method according to the seventh embodiment can be applied to any of the first embodiment to the sixth embodiment and their modifications.

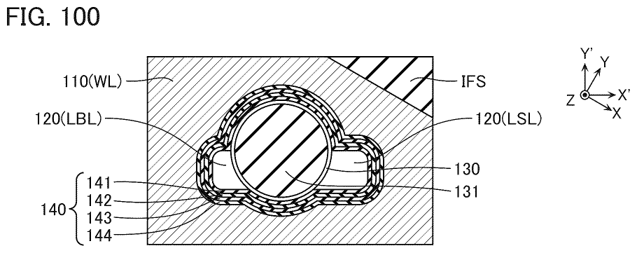

FIG. 100 is a schematic cross-sectional view for describing the semiconductor memory device according to the seventh embodiment. FIG. 100 illustrates a cross-section corresponding to FIG. 7.

When the manufacturing method according to the seventh embodiment is employed, a center of the circle inscribed in the opening 130A might not coincide with a central position in the X′-direction and a central position in the Y′-direction of the rectangle circumscribing in the opening 720A. As a result, in an example illustrated in FIG. 100, centers of the circles corresponding to the inner peripheral surface and the outer peripheral surface of the semiconductor layer 130 and the like do not coincide with a central position in the X′-direction and a central position in the Y′-direction of the rectangle circumscribing the pair of conductor columns 120.

As described above, here, in order to obtain the memory pillar MP of the NOR flash memory that includes the local bit line LBL and the local source line LSL extending in the Z-direction, the plurality of memory cells MC connected in parallel between the local bit line LBL and the local source line LSL, and the plurality of word lines WL connected to the gate electrodes of these plurality of memory cells MC, for example, it may be considered to form holes and the like as appropriate respectively corresponding to the local bit line LBL, the local source line LSL, the channel regions of the memory cells MC, and the like. However, with such a method, it is necessary to precisely position these plurality of holes, which increases the manufacturing difficulty.

For example, the hole corresponding to the local bit line LBL and the hole corresponding to the local source line LSL both need to be in contact with the hole corresponding to the channel regions of the memory cells MC. On the other hand, the hole corresponding to the local bit line LBL and the hole corresponding to the local source line LSL need to be kept from coming into contact with one another.

Here, in the seventh embodiment, the positioning of the opening 720A and the opening 130A is also performed. However, the opening 720A and the opening 130A only suffice to overlap one another such that the openings 120A are formed on both sides in the X′-direction of the opening 130A, and the positioning is relatively easy. As described above, the manufacturing method of the embodiment makes it possible to form each of the openings 120A and the opening 130A in an appropriate manner. Therefore, the manufacturing method according to this embodiment makes it possible to easily achieve a semiconductor memory device.

### Eighth Embodiment

The above-described embodiments and modifications have been described in the context of their application to the NOR flash memory. However, these structures can also be applied to semiconductor devices other than the NOR flash memory. An example of applying the same structure as the semiconductor memory device according to the first embodiment to a product-sum operation device as an eighth embodiment is described below.

The product-sum operation device according to the eighth embodiment is basically configured similarly to the semiconductor memory device according to the first embodiment. However, a peripheral circuit of the product-sum operation device according to the eighth embodiment is different from the peripheral circuit PC (FIG. 1) of the semiconductor memory device according to the first embodiment.

The peripheral circuit according to the eighth embodiment, for example, applies voltages corresponding to magnitudes of weights to the respective plurality of word lines WL in the plurality of memory blocks BLK when performing a product-sum operation. In addition, voltages corresponding to input data to be used in the product-sum operation are applied to the plurality of source lines SL. A current flows through each memory cell MC according to a threshold voltage and a voltage of the word line WL (gate voltage). A sum of the currents flowing through the plurality of memory cells MC in a corresponding memory pillar MP flows through each local bit line LBL. In addition, the sum of the currents flowing through respective local bit lines LBL flows through each bit line BL. The peripheral circuit acquires each current flowing through each bit line BL as a result of the product-sum operation.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a plurality of conductive layers stacked in a stacking direction;
a first conductor column and a second conductor column extending in the stacking direction and arranged in a first direction intersecting with the stacking direction;
an insulating column extending in the stacking direction and provided between the first conductor column and the second conductor column;
a semiconductor layer formed along an outer peripheral surface of the insulating column, connected to the first conductor column and the second conductor column, and opposed to the plurality of conductive layers; and
a memory film provided between the plurality of conductive layers and the semiconductor layer, wherein
in a cross-section intersecting with the stacking direction,
at least a part of an outer peripheral surface of the semiconductor layer is formed approximately along a shape of a circle, an ellipse, or an oval, and
at least a part of the first conductor column and at least a part of the second conductor column are provided outside the shape of the circle, the ellipse, or the oval.

2. The semiconductor device according to claim 1, wherein
in the cross-section intersecting with the stacking direction, one of the plurality of conductive layers surrounds the first conductor column, the second conductor column, and the semiconductor layer.

3. The semiconductor device according to claim 1, wherein
the semiconductor layer is provided between the first conductor column and the second conductor column, and
a surface on a second conductor column side of the first conductor column and a surface on a first conductor column side of the second conductor column are connected to the semiconductor layer.

4. The semiconductor device according to claim 3, wherein
in the cross-section intersecting with the stacking direction, lengths in a second direction intersecting with the stacking direction and the first direction of the first conductor column and the second conductor column are smaller than lengths in the first direction and the second direction of the semiconductor layer.

5. The semiconductor device according to claim 3, wherein
the semiconductor layer is continuous in the stacking direction within a range of the stacking direction in which the plurality of conductive layers are provided.

6. The semiconductor device according to claim 1, wherein
a surface on a second conductor column side of the first conductor column and a surface on a first conductor column side of the second conductor column are connected to the insulating column, and
the semiconductor layer is divided in a second direction intersecting with the stacking direction and the first direction via the first conductor column and the second conductor column.

7. The semiconductor device according to claim 6, wherein
in the cross-section intersecting with the stacking direction, lengths in the second direction of the first conductor column and the second conductor column is smaller than lengths in the first direction and the second direction of the insulating column.

8. The semiconductor device according to claim 6, wherein
the semiconductor layer is divided in the stacking direction in correspondence with the plurality of conductive layers.

9. The semiconductor device according to claim 1, wherein
a surface on a second conductor column side of the first conductor column and a surface on a first conductor column side of the second conductor column are connected to the insulating column, and
the semiconductor layer is formed along outer peripheral surfaces of the first conductor column, the second conductor column, and the insulating column.

10. The semiconductor device according to claim 9, wherein
in the cross-section intersecting with the stacking direction, a portion other than a contact portion with the first conductor column and the second conductor column of an outer peripheral surface of the insulating column is in contact with the semiconductor layer, and
a surface on a side opposite to the second conductor column of the first conductor column, a surface on a side opposite to the first conductor column of the second conductor column, and both surfaces in a second direction intersecting with the stacking direction and the first direction of the first conductor column and the second conductor column are in contact with the semiconductor layer.

11. The semiconductor device according to claim 9, wherein
in the cross-section intersecting with the stacking direction, lengths in a second direction intersecting with the stacking direction and the first direction of the first conductor column and the second conductor column are smaller than lengths in the first direction and the second direction of the insulating column.

12. The semiconductor device according to claim 9, wherein
the semiconductor layer is divided in the stacking direction in correspondence with the plurality of conductive layers.

13. The semiconductor device according to claim 1, wherein
each of the first conductor column and the second conductor column has a resistivity lower than a resistivity of the semiconductor layer.

14. The semiconductor device according to claim 1, wherein
the first conductor column includes a first semiconductor column containing an impurity,
the second conductor column includes a second semiconductor column containing an impurity, and
the semiconductor layer does not contain any impurity, or a concentration of an impurity in the semiconductor layer is lower than a concentration of the impurity in the first semiconductor column and a concentration of the impurity in the second semiconductor column.

15. The semiconductor device according to claim 1, wherein
the memory film includes an electric charge accumulating film continuous in the stacking direction within a range of the stacking direction in which the plurality of conductive layers are provided.

16. The semiconductor device according to claim 1, wherein
the memory film includes an electric charge accumulating film divided in the stacking direction in correspondence with the plurality of conductive layers.

17. The semiconductor device according to claim 16, wherein
the semiconductor layer includes a plurality of semiconductor portions arranged in the stacking direction in correspondence with the plurality of conductive layers,
the memory film includes a tunnel insulating film continuous in the stacking direction within a range of the stacking direction in which the plurality of conductive layers are provided and formed along an unevenness including the plurality of semiconductor portions arranged in the stacking direction, outer peripheral surfaces of the first conductor column and the second conductor column, and an outer peripheral surface of the insulating column.

18. The semiconductor device according to claim 1, wherein
the memory film includes a silicon nitride, a floating gate, or a ferroelectric film.

19. A semiconductor device comprising:
a plurality of conductive layers stacked in a stacking direction;
a first conductor column and a second conductor column extending in the stacking direction and arranged in a first direction intersecting with the stacking direction;
a semiconductor layer provided between the first conductor column and the second conductor column, connected to a surface on a second conductor column side of the first conductor column and a surface on a first conductor column side of the second conductor column, and opposed to the plurality of conductive layers; and
a memory film provided between the plurality of conductive layers and the semiconductor layer, wherein
in a cross-section intersecting with the stacking direction, lengths in a second direction intersecting with the stacking direction and the first direction of the first conductor column and the second conductor column are smaller than lengths in the first direction and the second direction of the semiconductor layer.

20. A semiconductor device comprising:
a plurality of conductive layers stacked in a stacking direction;
a first conductor column and a second conductor column extending in the stacking direction and arranged in a first direction intersecting with the stacking direction;
an insulating column extending in the stacking direction, provided between the first conductor column and the second conductor column, and connected to a surface on a second conductor column side of the first conductor column and a surface on a first conductor column side of the second conductor column;
a semiconductor layer connected to both surfaces in a second direction intersecting with the stacking direction and the first direction of the first conductor column, both surfaces in the second direction of the second conductor column, and a portion other than a contact portion with the first conductor column and the second conductor column of an outer peripheral surface of the insulating column, and opposed to the plurality of conductive layers; and
a memory film provided between the plurality of conductive layers and the semiconductor layer, wherein
in a cross-section intersecting with the stacking direction, lengths in the second direction of the first conductor column and the second conductor column are smaller than lengths in the first direction and the second direction of the insulating column.
